(19) United States
(12) Patent Application Publication
(10) Pub. No.: US 2015/0332902 A1
(43) Pub. Date: Nov. 19, 2015

(54) SPUTTERING TARGET, OXIDE SEMICONDUCTOR THIN FILM, AND METHODS FOR PRODUCING THESE

(71) Applicant: Idemitsu Kosan Co, Ltd., Chiyoda-ku, Tokyo (JP)

(72) Inventor: Kazuaki EBATA, Sodegaura-shi, Chiba (JP)

(73) Assignee: Idemitsu Kosan Co, Ltd., Chiyoda-ku, Tokyo (JP)

(21) Appl. No.: 14/436,824

(22) PCT Filed: Oct. 16, 2013
(86) PCT No.: PCT/JP2013/006146

§ 371 Date: Jul. 1, 2015

(30) Foreign Application Priority Data
Oct. 18, 2012 (JP) 2012-230512
Apr. 12, 2013 (JP) 2013-084274

(51) Int. Cl. H01J 37/34; H01L 27/12; C23C 14/34

(52) U.S. Cl. CPC H01J 37/3429; C23C 14/3414; C23C 14/3464; H01L 27/1225

(57) ABSTRACT

A sputtering target that includes an oxide including an indium element (In), a tin element (Sn), a zinc element (Zn) and an aluminum element (Al) and comprises a homologous structure compound represented by In₂O₃(ZnO)ₙ (n is 2 to 20) and a spinet structure compound represented by Zn₂SnO₄.

### TECHNICAL FIELD

The invention relates to a sputtering target, an oxide semiconductor thin film and a method for producing the same.

### BACKGROUND ART

Field effect transistors, such as a thin film transistor (TFT), are widely used as the unit electronic device of a semiconductor memory integrated circuit, a high frequency signal amplification device, a device for a liquid crystal drive, or the like, and they are electronic devices which are currently most widely put into practical use. Among these, with significant development in displays in recent years, in various displays such as a liquid crystal display (LCD), an electroluminescence display (EL) and a field emission display (FED), a TFT is frequently used as a switching device which drives a display by applying a driving voltage to a display device.

As a material of a semiconductor layer (channel layer) which is a main component of a field effect transistor, a silicon semiconductor compound is used most widely. Generally, a silicon single crystal is used for a high frequency amplification device, a device for integrated circuits or the like which need high-speed operation. On the other hand, an amorphous silicon semiconductor (amorphous silicon) is used for a device for driving a liquid crystal in order to satisfy the demand for realizing a large-area display.

A thin film of amorphous silicon can be formed at relatively low temperatures. However, the switching speed thereof is slow as compared with that of a crystalline thin film. Therefore, when it is used as a switching device that drives a display, it may be unable to follow the display of a high-speed animation. Specifically, amorphous silicon having a mobility of 0.5 to 1 cm²/Vs could be used in a liquid crystal television of which the resolution is VGA. However, if the resolution is equal to or more than SXGA, UXGA and QXGA, a mobility of 2 cm²/Vs or more is required. Moreover, if the driving frequency is increased in order to improve the image quality, a further higher mobility is required.

As for a crystalline silicon-based thin film, although it has a high mobility, there are problems that a large amount of energy and a large number of steps are required for the production, and that large-area film formation is difficult. For example, when a silicon-based thin film is crystallized, a high temperature of 800° C. or more or laser annealing which needs expensive equipment is required. In the case of a crystalline silicon-based thin film, the device configuration of a TFT is normally restricted to a top-gate configuration, and hence, reduction in production cost such as decrease in number of masks is difficult.

In order to solve the problem, a thin film transistor using an oxide semiconductor film formed of indium oxide, zinc oxide and gallium oxide has been studied. In general, an oxide semiconductor thin film is formed by sputtering using a target (sputtering target) composed of an oxide sintered body.

For example, a target formed of a homologous crystal structure compound such as In₂Ga₂ZnO₇ and InGaZnO₄ is known (Patent Documents 1, 2 and 3). However, in this target, in order to increase the sintering density (relative density), it is required to conduct sintering in an oxidizing atmosphere. In this case, in order to reduce the resistance of the target, a reduction treatment at a high temperature is required to be conducted after sintering. Further, if the target is used for a long period of time, problems arise that the properties of the resulting film or the film-forming speed largely change; abnormal discharge due to abnormal growth of InGaZnO₄ or In₂Ga₂ZnO₇ occurs; particles are frequently generated during film formation or the like. If abnormal discharge occurs frequently, plasma discharge state becomes unstable, and as a result, stable film-formation is not conducted, adversely affecting the film properties.

On the other hand, a thin film transistor that is obtained by using an amorphous oxide semiconductor film that does not contain gallium and is composed of indium oxide and zinc oxide has been proposed (Patent Document 4). However, this thin film transistor has a problem that a normally-off operation of a TFT cannot be realized if the oxygen partial pressure at the time of film formation is not increased.

Further, studies have been made on a sputtering target for forming a protective layer of an optical information recording medium, that is obtained by adding an additive element such as Ta, Y, Si or the like to an In₂O₃—SnO₂—ZnO-based oxide composed mainly of tin oxide (Patent Documents 5 and 6). However, these targets are not used for forming an oxide semiconductor and they have problems that an agglomerate of an insulating material is likely to be formed easily, whereby the resistance is increased or abnormal discharge tends to occur easily.

### RELATED ART DOCUMENTS

### Patent Documents

Patent Document 1: JP-A-H08-245220

Patent Document 2: JP-A-2007-73312

Patent Document 3: WO2009/084537

Patent Document 4: WO2005/088726

Patent Document 5: WO2005/078152

Patent Document 6: WO2005/078153

### SUMMARY OF THE INVENTION

An object of the invention is to provide a high-density and low-resistant sputtering target.

Another object of the invention is to provide a thin film transistor having a high field effect mobility and high reliability.

According to the invention, the following sputtering targets or the like are provided.

1. A sputtering target that comprises an oxide comprising an indium element (In), a tin element (Sn), a zinc element (Zn) and an aluminum element (Al) and comprises a homologous structure compound represented by In₂O₃(ZnO)ₙ (n is 2 to 20) and a spinel structure compound represented by Zn₂SnO₄.
2. The sputtering target according to 1, wherein Al is in a solid-solution state in the homologous structure compound represented by In₂O₃(ZnO)ₙ.
3. The sputtering target according to 1 or 2, wherein the homologous structure compound represented by In₂O₃(ZnO)ₙ is one or more selected from a homologous structure compound represented by In₂Zn₇O₁₀, a homologous structure compound represented by In₂Zn₅O₈, a homologous structure compound represented by In₂Zn₄O₇, a homologous structure compound represented by In₂Zn₃O₆ and a homologous structure compound represented by In₂Zn₂O₅.
4. The sputtering target according to any one of 1 to 3 that does not comprise a bixbyite structure compound represented by In₂O₃.
5. The sputtering target according to any one of 1 to 4 that satisfies the atomic ratios shown in the formulas (1) to (4):

0.08≦In/(In+Sn+Zn+Al)≦0.50 (1)

0.01≦Sn/(In+Sn+Zn+Al)≦0.30 (2)

0.30≦Zn/(In+Sn+Zn+Al)≦0.90 (3)

0.01≦Al/(In+Sn+Zn+Al)≦0.30 (4)

wherein in the formulas, In, Sn, Zn and Al are respectively an atomic ratio of the indium element, the tin element, the zinc element and the aluminum element in the sputtering target.
6. The sputtering target according to any one of 1 to 5 that has a relative density of 98% or more.
7. The sputtering target according to any one of 1 to 6 that has a bulk specific resistance of 5 mΩcm or less.
8. A method for producing a sputtering target, comprising:

a mixing step in which one or more compounds are mixed to prepare a mixture that at least comprises an indium element (In), a zinc element (Zn), a tin element (Sn) and an aluminum element (Al);

a forming step in which the prepared mixture is formed to obtain a formed body; and

a sintering step in which the formed body is sintered,

wherein, in the sintering step, sintering of a formed body of the oxide comprising an indium element, a zinc element, a tin element and an aluminum element is conducted by elevating the temperature of the formed body at an average temperature-elevating speed of 0.1 to 0.9° C./min from 700 to 1400° C. and by retaining the formed body at 1200 to 1650° C. for 5 to 50 hours.
9. The method for producing a sputtering target according to 8, wherein a first average temperature-elevating speed from 400° C. or higher and lower than 700° C. is 0.2 to 1.5° C./min, a second average temperature-elevating speed from 700° C. or higher and lower than 1100° C. is 0.15 to 0.8° C./min, and a third average temperature-elevating speed from 1100° C. or higher and 1400° C. or lower is 0.1 to 0.5° C./min, and

the relationship between the first to third average temperature-elevating speeds satisfies the relationship of:

the first average temperature-elevating speed>the second average temperature-elevating speed>the third average temperature-elevating speed.

10. An oxide semiconductor thin film obtained by a sputtering method with the use of the sputtering target according to any one of 1 to 7.
11. A method for producing an oxide semiconductor thin film, wherein the film is formed by a sputtering method with the use of the sputtering target according to any one of 1 to 7 in an atmosphere of a mixed gas that comprises: one or more selected from water vapor, an oxygen gas and a nitrous oxide gas; and a rare gas.
12. The method for producing an oxide semiconductor thin film according to 11, wherein the mixed gas is a mixed gas that at least comprises a rare gas and water vapor.
13. The method for producing an oxide semiconductor thin film according to 12, wherein the ratio of the water vapor contained in the mixed gas is 0.1% to 25% in terms of a partial pressure ratio.
14. The method for producing an oxide semiconductor thin film according to any one of 11 to 13 comprising:

transporting substrates in sequence to positions opposing to 3 or more of the sputtering targets arranged in parallel with a prescribed interval in a vacuum chamber;

applying a negative potential and a positive potential alternately from an AC power source to each of the targets; and

causing plasma to be generated on the target by applying an output from at least one AC power source between two or more targets divergently connected to this AC power source while switching the target to which a potential is applied, thereby forming a film on a substrate surface.

15. The method for producing an oxide semiconductor thin film according to 14, wherein the AC power density of the AC power source is 3 W/cm² or more and 20 W/cm² or less.
16. The method for producing an oxide semiconductor thin film according to 14 or 15, wherein the frequency of the AC power source is 10 kHz to 1 MHz.
17. A thin film transistor comprising, as a channel layer, the oxide semiconductor thin film formed by the method for producing an oxide semiconductor thin film according to any one of 11 to 16.
18. The thin film transistor according to 17 that has a field effect mobility of 15 cm²Ns or more.
19. A display comprising the thin film transistor according to 17 or 18.

According to the invention, it is possible to provide a high-density and low-resistant sputtering target.

According to the invention, it is possible to provide a thin film transistor having a high field effect mobility and high reliability.

### BRIEF DESCRIPTION OF THE DRAWINGS

FIG. 1 is a view showing a sputtering apparatus used in one embodiment of the invention;

FIG. 2 is a view showing an X-ray diffraction chart of a sintered body obtained in Example 1;

FIG. 3 is a view showing an X-ray diffraction chart of a sintered body obtained in Example 2;

FIG. 4 is a view showing an X-ray diffraction chart of a sintered body obtained in Example 3;

FIG. 5 is a view showing an X-ray diffraction chart of a sintered body obtained in Example 18;

FIG. 6 is a view showing an X-ray diffraction chart of a sintered body obtained in Example 19;

FIG. 7 is a view showing an X-ray diffraction chart of a sintered body obtained in Example 20;

FIG. 8 is a view showing an X-ray diffraction chart of a sintered body obtained in Example 21; and

FIG. 9 is a view showing an X-ray diffraction chart of a sintered body obtained in Example 22.

### MODE FOR CARRYING OUT THE INVENTION

Hereinbelow, a detailed explanation will be made on the sputtering target or the like of the invention. The invention is, however, not limited to the following embodiment and examples.

### [Sputtering Target]

The sputtering target of the invention is composed of an oxide that comprises an indium element (In), a tin element (Sn), a zinc element (Zn) and an aluminum element (Al), and comprises a homologous structure compound represented by In₂O₃(ZnO)ₙ (n is 2 to 20) and a spinel structure compound represented by Zn₂SnO₄.

Due to the presence of a homologous structure compound represented by In₂O₃(ZnO)ₙ (n is 2 to 20) in the sputtering target, the relative density of the target can be increased and the specific resistance of the target can be decreased, whereby abnormal discharge can be suppressed.

The homologous crystal structure is a crystal formed of a long-period “natural superlattice” structure in which crystal layers of different substances are stacked. If the crystal period or the thickness of each thin film layer is on a nanometer level, a homologous structure compound can exhibit inherent characteristics that differ from the characteristics of a single substance or a mixed crystal in which the layers are uniformly mixed.

The homologous structure compound represented by In₂O₃(ZnO)ₙ that is contained in the target may be a single compound or a mixture of two or more compounds.

As for the homologous structure compound represented by In₂O₃(ZnO)ₙ, when n is an integer, for example, n is preferably 2 to 15, more preferably 2 to 10, further preferably 2 to 7, and most preferably 2 to 5.

That is, the homologous structure compound represented by In₂O₃(ZnO)ₙ is most preferably one or more selected from a homologous structure compound represented by In₂Zn₅O₈, a homologous structure compound represented by In₂Zn₄O₇, a homologous structure compound represented by In₂Zn₃O₆ and a homologous structure compound represented by In₂Zn₂O₅.

The homologous structure compound in the target can be confirmed by X-ray diffraction. For example, it can be confirmed by a fact that an X-ray diffraction pattern measured from powder obtained by pulverizing the target or an X-ray diffraction pattern measured directly from the target corresponds to an X-ray diffraction pattern of the crystal structure of the homologous phase assumed from the composition ratio. Specifically, it can be confirmed by the fact that the pattern is coincident with the crystal structure X-ray diffraction pattern of the homologous phase obtained from the JCPDS (Joint Committee of Powder Diffraction Standards) card or ICSD (The Inorganic Crystal Structure Database).

The homologous structure compound represented by In₂Zn₇O₁₀ can be retrieved from ICSD by X-ray diffraction, and shows a peak pattern of ICSD #162453 or a similar (shifted) pattern. The homologous structure compound represented by In₂Zn₅O₈ can be retrieved from ICSD by X-ray diffraction, and shows a peak pattern of ICSD #162452 or a similar (shifted) pattern. The homologous structure compound represented by In₂Zn₄O₇ can be retrieved from ICSD by X-ray diffraction, and shows a peak pattern of ICSD #162451 or a similar (shifted) pattern. The homologous structure compound represented by In₂Zn₃O₆ can be retrieved from ICSD by X-ray diffraction, and shows a peak pattern of ICSD #162450 or a similar (shifted) pattern. The homologous structure compound represented by In₂Zn₂O₅ is a compound showing a peak pattern of No. 20-1442 of JCPDS database or a similar (shifted) peak pattern.

In the sputtering target of the invention, it is preferred that Al is in a solid-solution state in a homologous structure compound represented by In₂O₃(ZnO)ₙ.

Due to the solid solution of Al³⁺ in the In³⁺ site of In₂O₃(ZnO)ₙ, deposition of Al₂O₃ can be suppressed. Deposition of Al₂O₃ may lead to an increase in resistance of a target, and may cause abnormal discharge easily. Therefore, abnormal discharge can be suppressed by suppressing deposition of Al₂O₃.

When Al³⁺ is in a solid-solution state in an In³⁺ site of In₂O₃(ZnO)ₙ (n is 2 to 20), since the ionic radius of an Al³⁺ ion is smaller than an In³⁺ ion, the lattice constant of In₂O₃(ZnO)ₙ (n is 2 to 20) becomes small. Therefore, by confirming whether the lattice constant of In₂O₃(ZnO)ₙ, in the target is smaller than the lattice constant of In₂O₃(ZnO)ₙ disclosed in the database of ICSD or JCPDS, it can be confirmed that whether Al is in a solid-solution state or not.

The lattice constant of In₂O₃(ZnO)ₙ (n is 2 to 20) in a target can be derived from an XRD measurement. For example, the homologous structure compound represented by In₂Zn₇O₁₀ can be retrieved from the ICSD database by X-ray diffraction, and the lattice constant disclosed in ICSD #162453 is a=3.3089 Å, b=3.3089 Å and c=73.699 Å. The homologous structure compound represented by In₂Zn₅O₈ can be retrieved by the ICSD database by X-ray diffraction, and the lattice constant disclosed in ICSD #162452 is a=3.3245 Å, b=3.3245 Å and c=58.093 Å. The homologous structure represented by In₂Zn₄O₇ can be retrieved from the ICSD database by X-ray diffraction and the lattice constant disclosed in ICSD #162451 is a=3.3362 Å, b=3.3362 Å and c=33.526 Å. The homologous structure of In₂Zn₃O₆ can be retrieved from the ICSD database by X-ray diffraction and the lattice constant disclosed in ICSD#162450 is a=3.3520 Å, b=3.3520 Å and c=42.488 Å. The homologous structure of In₂Zn₂O₅ can be retrieved from the JCPDS database by X-ray diffraction, and the lattice constant disclosed in No. 20-1442 of the JCPDS card is a=3.376 Å, b=3.376 Å and c=23.154 Å.

Due to the presence of a spinel structure compound represented by Zn₂SnO₄ in a sputtering target, abnormal grain growth of crystals in the oxide that constitutes the target can be suppressed. Abnormal grain growth may cause abnormal discharge during sputtering. As stated in “Crystal Chemistry” (Mitsuoki Nakahira, Kodansha Ltd., 1973) or the like, the spinel structure is normally of an AB₂X₄ type or A₂BX₄ type, and a compound having such a crystal structure is referred to as a spinel structure compound. In general, in a spinel structure, an anion (normally, oxygen) is hexagonally close-packed, and an anion is present in part of the tetrahedral interstitial site or the octahedral interstitial site thereof. A substitutional solid solution in which a part of atoms or ions in a crystal structure are replaced by other atoms and an interstitial solid solution in which other atoms are added to a position between lattices are included in a spinel structure compound.

Presence or absence of the spinel structure compound represented by Zn₂SnO₄ in the sputtering target can be confirmed by X-ray diffraction.

The spinel structure compound represented by Zn₂SnO₄ shows a peak pattern of No. 24-1470 of the JCPDS database or a similar (shifted) pattern.

It is preferred that the sputtering target of the invention do not comprise a bixbyite structure compound represented by In₂O₃.

The bixbyite structure compound (or a C-type crystal structure of a rare-earth oxide) also refers to as a C-type rare-earth oxide or Mn₂O₃ (I) type oxide. As stated in the “Technology of Transparent Conductive Film” (published by Ohmsha Ltd., edited by Japan Society for the Promotion of Science, transparent oxide/photoelectron material 166 committee, 1999) or the like, this compound has a chemical stoichiometric ratio of M₂X₃ (M is a cation and X is an anion, which is normally an oxygen ion), and one unit cell is formed of 16 M₂X₃ molecules and total 80 atoms (the number of M is 32 and the number of X is 48).

The bixbyite structure compound represented by In₂O₃ includes a substitutional solid solution in which a part of atoms or ions in a crystal structure are replaced by other atoms and an interstitial solid solution in which other atoms are added to a position between lattices.

Presence or absence of a bixbyite structure compound represented by In₂O₃ in a sputtering target can be confirmed by X-ray diffraction.

The bixbyite structure compound represented by In₂O₃ shows a peak pattern of No. 06-0416 of JCPDS (Joint Committee on Powder Diffraction Standards) database or a similar (shifted) pattern.

The sputtering target of the invention may further contain, in addition to a homologous structure compound represented by In₂O₃(ZnO)ₙ (n is 2 to 20) and a spinel structure compound represented by Zn₂SnO₄, a homologous structure compound represented by InAlO₃(ZnO)ₙ (n is 2 to 20).

An oxide constituting the sputtering target of the invention containing an indium element (In), a tin element (Sn), a zinc element (Zn) and an aluminum element (Al) satisfy the following atomic ratio. When the oxide satisfies the following atomic ratio, the relative density of the target can be 98% or more and the bulk resistance can be 5 mΩcm or less.

0.08≦In/(In+Sn+Zn+Al)≦0.50 (1)

0.01≦Sn/(In+Sn+Zn+Al)≦0.30 (2)

0.30≦Zn/(In+Sn+Zn+Al)≦0.90 (3)

0.01≦Al/(In+Sn+Zn+Al)≦0.30 (4)

wherein In, Sn, Zn and Al are respectively an atomic ratio of an indium element, a tin element, a zinc element and an aluminum element in the sputtering target.

In the formula (1), if the atomic ratio of the In element is less than 0.08, the bulk resistance value of the sputtering target may become high, resulting in impossibility in DC sputtering.

On the other hand, if the atomic ratio of the In element exceeds 0.50, a bixbyite structure compound represented by In₂O₃ may be formed in the target. If the target comprises a bixbyite structure compound represented by In₂O₃ in addition to In₂O₃(ZnO)ₙ (n is 2 to 20) and a spinel structure compound represented by Zn₂SnO₄, the sputtering speed varies depending on the crystal phase, and hence, parts remaining unremoved may be formed, whereby abnormal discharge may occur. Further, at the time of sintering, abnormal grain growth may occur at a place where In₂O₃ is agglomerated, voids may remain, and the density of the entire sintered body may not be improved.

For the reasons mentioned above, the formula (1) is 0.08≦In/(In+Sn+Zn+Al)≦0.50, preferably 0.12≦In/(In+Sn+Zn+Al)≦0.50, and more preferably 0.15≦In/(In+Sn+Zn+Al)≦0.40.

In the formula (2), if the atomic ratio of the Sn element is less than 0.01, the sintered body density is not fully improved, and the bulk resistance of the target may become high. On the other hand, if the atomic ratio of the Sn element exceeds 0.30, SnO₂ tends to be deposited easily, and the deposited SnO₂ may cause abnormal discharge.

For the reason mentioned above, the formula (2) is 0.01≦Sn/(In+Sn+Zn+Al)≦0.30, preferably 0.03≦Sn/(In+Sn+Zn+Al)≦0.25, and more preferably 0.05≦Sn(In+Sn+Zn+Al)≦0.15.

In the formula (3), if the atomic ratio of the Zn element is less than 0.30, the homologous structure represented by In₂O₃(ZnO)ₙ (n is 2 to 20) may not be formed. On the other hand, if the atomic ratio of the Zn element exceeds 0.90, ZnO tends to be deposited easily, and the deposited ZnO may cause abnormal discharge.

For the reason mentioned above, the formula (3) is 0.30≦Zn/(In+Sn+Zn+Al)≦0.90, preferably 0.40≦Zn/(In+Sn+Zn+Al)≦0.80 and more preferably 0.45≦Zn(In+Sn+Zn+Al)≦0.75.

In the formula (4), if the atomic ratio of the Al element is less than 0.01, the target resistance may not be fully lowered. If a channel layer of a TFT is formed by using a target, the reliability of a TFT may be deteriorated. On the other hand, if the atomic ratio of the Al element exceeds 0.30, Al₂O₃ may be generated in the target, causing abnormal discharge.

For the reasons mentioned above, the formula (4) is 0.01≦Al/(In+Sn+Zn+Al)≦0.30, preferably 0.01≦Al/(In+Sn+Zn+Al)≦0.20, and more preferably 0.01≦Al(In+Sn+Zn+Al)≦0.15.

The atomic ratio of each of elements contained in the target can be obtained by quantitatively analyzing the elements contained with Induction Coupled Plasma Atomic Emission Spectrometry (ICP-AES).

Specifically, when a solution sample is nebulized using a nebulizer, and introduced into an argon plasma (about 6000 to about 8000° C.), each element contained in the sample absorbs thermal energy, and is excited, and the orbital electrons migrate from the ground state to the orbital at a high energy level. The orbital electrons then migrate to the orbital at a lower energy level within about 10⁻⁷ to about 10⁻⁸ seconds. In this case, the difference in energy is emitted as light. Since the emitted light has an element-specific wavelength (spectral line), the presence or absence of each element can be determined based on the presence or absence of the spectral line (qualitative analysis).

Since the intensity (luminous intensity) of each spectral line is in proportion to the number of each element contained in the sample, the element concentration in the sample can be determined by comparison with a standard solution having a known concentration (quantitative analysis).

After specifying the elements contained in the sample by qualitative analysis, the content of each element is determined by quantitative analysis, and the atomic ratio of each element is calculated from the results.

The oxide constituting a sputtering target may comprise inevitably mixed-in impurities other than In, Sn, Zn and Al as long as the effects of the invention are not impaired. The sputtering target may substantially comprise only In, Sn, Zn and Al. In the invention, the “substantially” means that 95 mass % or more and 100 mass % or less (preferably 98 mass % or more and 100 mass % or less) of the metal element of the sputtering target is In, Sn, Zn and Al.

It is preferred that the sputtering target of the invention have a relative density of 98% or more. Particularly, if an oxide semiconductor is deposited on a large-sized substrate (1G or more) with an increased sputtering output, it is preferred that the relative density be 98% or more.

The relative density is a density which is relatively calculated for the theoretical density which is calculated from the weighted average. The density calculated from the weighted average of the density of each raw material is a theoretical density, which is assumed to be 100%.

If the relative density is 98% or more, stable sputtering state is maintained. When the film is formed by increasing the sputtering power on a large substrate, if the sputtering target has a relative density smaller than 98%, the target surface may be blackened or abnormal discharge may occur. The relative density is preferably 98.5% or more, with 99% or more being more preferable.

The relative density of the target can be measured by the Archimedian method. The relative density is preferably 100% or less. If the relative density is 100% or less, metal particles may not be generated easily in a sintered body, and formation of a lower oxide may be suppressed. Therefore, it is not required to control the oxygen supply amount during deposition strictly.

Further, the density can be adjusted by a post treatment or the like such as a heat treatment in the reductive atmosphere after sintering. As the reductive atmosphere, an atmosphere such as argon, nitrogen and hydrogen, or an atmosphere of a mixture of these gases can be used.

The bulk specific resistance (conductivity) of the target is preferably 5 mΩcm or less, and more preferably 3 mΩcm or less. If the bulk specific resistance of the target is 5 mΩcm or less, abnormal discharge can be suppressed.

The bulk specific resistance mentioned above can be measured by a four point probe method using a resistivity meter.

It is desired that the maximum particle size of the crystal in the oxide constituting the sputtering target be 8 μm or less. Due to the crystal maximum particle size of 8 μm or less, formation of nodules can be suppressed.

When the target surface is ground by sputtering, the grinding speed differs depending on the direction of the crystal, whereby unevenness is generated on the target surface. The size of this unevenness varies depending on the particle size of the crystal present in the sintered body. It is assumed that, in the target formed of an oxide having a large crystal particle size, a greater scale of unevenness occurs, and nodules are generated from this convex part.

The maximum particle size of the crystal of the sputtering target is obtained as follows. If the sputtering target has a circular shape, at five locations in total, i.e. the central point (one) and the points (four) which are on the two central lines crossing orthogonally at this central point and are middle between the central point and the peripheral part, or if the sputtering target has a square shape, at five locations in total, i.e. the central point (one) and middle points (four) between the central point and the corner of the diagonal line of the square, the maximum diameter is measured for the biggest particle observed within a 100-μm square. The maximum particle size is the average value of the particle size of the biggest particle present in each of the frames defined by the five locations. As for the particle size, the longer diameter of the crystal particle is measured. The crystal particles can be observed by the scanning electron microscopy (SEM).

### [Method for Producing a Sputtering Target]

The method for producing a sputtering target of the invention comprises the following two steps, for example:

(1) A step in which raw material compounds are mixed and formed to obtain a formed body
(2) A step in which the above-mentioned formed body is sintered

Hereinbelow, an explanation will be made based on these steps.

(1) A step in which raw material compounds are mixed and formed to obtain a formed body

No specific restrictions are imposed on the raw material compounds, and a compound containing one or more element selected from In, Sn, Zn and Al can be used. It is preferred that a mixture of the raw material compounds to be used satisfy the following atomic ratio:

0.08≦In/(In+Sn+Zn+Al)≦0.50 (1)

0.01≦Sn/(In+Sn+Zn+Al)≦0.30 (2)

0.30≦Zn/(In+Sn+Zn+Al)≦0.90 (3)

0.01≦Al/(In+Sn+Zn+Al)≦0.30 (4)

As the compound containing one or more element selected from In, Sn, Zn and Al, a combination of indium oxide, tin oxide, zinc oxide and an aluminum oxide, or the like can be mentioned.

It is preferred that the raw material compounds mentioned above be powder.

It is preferred that the raw material compounds be a mixed powder of indium oxide, tin oxide, zinc oxide and aluminum oxide.

If a simple metal is used as a raw material, when a combination of indium oxide, tin oxide, zinc oxide and aluminum metal is used as raw material powders, for example, metal particles of aluminum may be present in the resulting sintered body. As a result, metal particles on the target surface are molten during film formation and hence cannot be emitted from the target, resulting in a great difference between the composition of the film and the composition of the sintered body.

If the raw material compound is powder, the average particle diameter of the raw material powder is preferably 0.1 μm to 1.2 μm, more preferably 0.1 μm to 1.0 μm. The average particle diameter of the raw material powder can be measured by a laser diffraction particle size distribution measuring apparatus or the like.

For example, an oxide containing In₂O₃ powder having an average particle diameter of 0.1 μm to 1.2 μm, SnO₂ powder having an average particle diameter of 0.1 μm to 1.2 μm, ZnO powder having an average particle diameter of 0.1 μm to 1.2 μm and Al₂O₃ powder having an average particle diameter of 0.1 μm to 1.2 μm is used as the raw material powder. They may be contained in an amount ratio that satisfies the above-mentioned formulas (1) to (4).

The method for mixing the raw material compound and forming the mixture is not particularly restricted, and a known method can be used. For example, a water-based solvent is compounded with raw material powders containing an oxide powder mixture including indium oxide powder, tin oxide powder, zinc oxide powder and aluminum oxide powder, and the resulting slurry is mixed for 12 hours or more. Then, the mixture is subjected to solid-liquid separation, dried and granulated, and the granulated product is then put in a mold and formed, whereby a formed body is obtained.

As for the method for mixing, a wet or dry ball mill, a vibration mill, a beads mill or the like can be used. In order to obtain uniform and fine crystal particles and voids, the most preferable method is a beads mill mixing method since it can pulverize the aggregate efficiently for a short period of time and can realize a favorably-dispersed state of additives.

When a ball mill is used for mixing, the mixing time is preferably 15 hours or more, more preferably 19 hours or more. If the mixing time is insufficient, a high-resistant compound such as Al₂O₃ may be generated in the sintered body finally obtained.

When a beads mill is used for pulverizing and mixing, the mixing time varies depending on the size of the apparatus used and the amount of slurry to be treated. However, the mixing time is controlled appropriately such that the particle distribution in the slurry becomes uniform, i.e. all of the particles have a particle size of 1 μm or less.

In any of mixing methods, it is preferred that an arbitral amount of a binder be added, and that mixing be conducted simultaneously with the addition of the binder. As the binder, polyvinyl alcohol, vinyl acetate or the like can be used.

For granulation of a raw material powder slurry obtained by mixing, it is preferable to use quick dry granulation. As the apparatus for quick dry granulation, a spray dryer is widely used. Specific drying conditions are determined according to conditions such as the concentration of slurry to be dried, the temperature of hot air used for drying and the amount of wind. For actually conducting the quick dry granulation, it is required to obtain optimum conditions in advance.

In the case of quick dry granulation, a homogeneous granulated powder can be obtained. That is, separation of In₂O₃ powder, SnO₂ powder, ZnO powder and Al₂O₃ powder due to the difference in the speed of sedimentation caused by the difference in specific gravity of the raw material powder can be prevented. If a target is made by using this homogeneous granulated powder, occurrence of abnormal discharge during sputtering due to the presence of Al₂O₃ or the like can be prevented.

The granulated powder obtained can normally be formed into a formed body by pressing at a pressure of 1.2 ton/cm² or more by means of a mold press or cold isostatic pressing (CIP), for example.

(2) A step in which a formed body is sintered

By sintering the obtained formed body, a sintered body can be obtained.

The above-mentioned sintering preferably includes a temperature-elevating step and a retaining step. In the temperature-elevating step, the temperature is elevated from 700 to 1400° C. at an average temperature-elevating speed of 0.1 to 0.9° C./min, and in the retaining step, retaining is conducted at a sintering temperature of 1200 to 1650° C. for 5 to 50 hours. The average temperature-elevating speed in a temperature range of 700 to 1400° C. is more preferably 0.2 to 0.5° C./min.

The average temperature-elevating speed in a temperature range of 700 to 1400° C. is a value obtained by dividing a difference in temperature between 700° C. and the achieving temperature of the temperature elevation by a time required for temperature elevation.

As for the above-mentioned temperature-elevating step, it is more preferred that the average temperature-elevating speed (first average temperature-elevating speed) in a temperature range of 400° C. or higher and lower than 700° C. is 0.2 to 2.0° C./min, and the average temperature-elevating speed (second average temperature-elevating speed) in a temperature range of 700° C. or higher and lower than 1100° C. is 0.05 to 1.2° C./min, and the average temperature-elevating speed (third average temperature-elevating speed) in a temperature range of 1100° C. or higher and 1400° C. or less is 0.02 to 1.0° C./min.

The first average temperature-elevating speed is more preferably 0.2 to 1.5° C./min. The second average temperature-elevating speed is more preferably 0.15 to 0.8° C./min, and more preferably 0.3 to 0.5° C./min. The third average temperature-elevating speed is preferably 0.1 to 0.5° C./min, and more preferably 0.15 to 0.4° C./min.

By the above-mentioned temperature-elevating step, generation of nodules at the time of sputtering can be suppressed more effectively.

If the first average temperature-elevating speed is 0.2° C./min or higher, the time required for sintering is not increased excessively, whereby the production efficiency can be increased. Further, since the first average temperature-elevating speed is 2.0° C./min or less, even if a binder is incorporated at the time of mixing in order to increase dispersibility, the binder is not remained, whereby occurrence of cracks or the like in the target can be suppressed.

If the second average temperature-elevating speed is 0.05° C./min or higher, the time required for sintering is not increased excessively, and crystals are not grown extraordinary, whereby generation of voids inside the resulting sintered body can be suppressed. Further, due to the second average temperature-elevating speed of 1.2° C./min or less, no distribution is formed at a position where sintering starts, whereby occurrence of curvature can be suppressed.

If the third average temperature-elevating speed is 0.02° C./min or higher, the time required for sintering is not increased excessively, and generation of composition deviation due to evaporation of Zn can be suppressed. If the third average temperature-elevating speed is 1.0° C./min or less, no tensile stress due to distribution of densification is generated, whereby the sintering density can be increased easily.

The relationship between these first to third average temperature-elevating speeds preferably satisfies the relationship of the second average temperature-elevating speed>the third average speed, further preferably satisfies the relationship of the first average temperature-elevating speed>the second average temperature-elevating speed>the third average temperature-elevating speed.

In particular, if the relationship of the second average temperature-elevating speed>the third average temperature-elevating speed is satisfied, generation of nodules can be expected to be suppressed further effectively if sputtering is conducted for a long period of time.

The temperature-elevating speed in a temperature range of 400° C. or higher and less than 700° C. is preferably in the range of 0.2 to 2.0° C./min.

The temperature-elevating speed in a temperature range of 700° C. or higher and less than 1100° C. is preferably in the range of 0.05 to 1.2° C./min.

The temperature-elevating speed in a temperature range of 1100° C. or higher and 1400° C. or less is preferably in the range of 0.02 to 1.0° C./min.

No specific restrictions are imposed on the temperature-elevating speed when the temperature of a formed body is elevated to a temperature exceeding 1400° C. and 1650° C. or less. The speed is normally about 0.15 to 0.4° C./min.

After completion of the temperature elevation, sintering is conducted by retaining at a sintering temperature of 1200 to 1650° C. for 5 to 50 hours (retaining step). The sintering temperature is preferably 1300 to 1600° C. The sintering time is preferably 10 to 20 hours.

If the sintering temperature is 1200° C. or higher or the sintering time is 5 hours or longer, Al₂O₃ or the like are not formed inside the sintered body, and abnormal discharge does not occur easily. If the firing temperature is 1650° C. or lower or the firing time is 50 hours or less, an increase in average crystal particle diameter due to significant crystal grain growth or generation of large voids does not occur, whereby lowering in sintered body strength or abnormal discharge can be suppressed.

As for the sintering method used in the invention, in addition to the pressureless sintering, a pressure sintering method such as hot pressing, oxygen pressurization and hot isostatic pressing or the like can be used. In respect of a decrease in production cost, possibility of mass production and easiness in production of a large-sized sintered body, it is preferable to use a pressureless sintering.

In the pressureless sintering, a formed body is sintered in the air or the oxidizing gas atmosphere. Preferably, a formed body is sintered in the oxidizing gas atmosphere. The oxidizing gas atmosphere is preferably an oxygen gas atmosphere. It is preferred that the oxygen gas atmosphere be an atmosphere having an oxygen concentration of 10 to 100 vol %, for example. In the above-mentioned method for producing a sintered body, the density of the sintered body can be further increased by introducing an oxygen gas atmosphere during the temperature-elevating step.

In order to allow the bulk resistance of the sintered body obtained in the above-mentioned firing step to be uniform in the entire target, a reduction step may be further provided, if necessary.

As the reduction method, a reduction treatment by a reductive gas, a reduction treatment by vacuum firing, a reduction treatment by an inert gas or the like can be given, for example.

In the case of a reduction treatment by a reductive gas, hydrogen, methane, carbon monoxide, or a mixed gas of these gases with oxygen or the like can be used. In the case of a reduction treatment by firing in an inert gas, nitrogen, argon, or a mixed gas of these gases with oxygen or the like can be used.

The temperature at the time of the above-mentioned reduction treatment is normally 100 to 800° C., preferably 200 to 800° C. The reduction treatment is conducted normally for 0.01 to 10 hours, preferably 0.05 to 5 hours.

In summary, in the method for producing a sintered body used in the invention, a water-based solvent is compounded with raw material powders containing mixed powder of indium oxide powder, zinc oxide powder and aluminum oxide powder, and the resulting slurry is mixed for 12 hours or longer. Thereafter, the slurry is subjected to solid-liquid separation, dried and granulated. Subsequently, the granulated product is put in a mold and formed. Then, the resulting formed product is subjected to a sintering step that includes a temperature-elevating step in which the temperature of the formed body is elevated in an oxygen-containing atmosphere at an average temperature-elevating speed of 0.1 to 0.9° C./min in a temperature range of 700 to 1400° C. and a retaining step in which the formed body is retained at a temperature of 1200 to 1650° C. for 5 to 50 hours, whereby a sintered body can be obtained.

By processing the sintered body obtained above, the sputtering target of the invention can be obtained. Specifically, by grinding the sintered body into a shape suited to be mounted in a sputtering apparatus, a sputtering target material is obtained. Then, the target material is bonded to a backing plate, whereby a sputtering target can be obtained.

In order to allow the sintered body to be a target material, the sintered body is ground by means of a surface grinder to allow the surface roughness Ra to be 0.5 μm or less, for example. Further, the sputtering surface of the target material may be subjected to mirror finishing, thereby allowing the average surface roughness thereof Ra to be 1000 Å or less.

For this mirror finishing (polishing), known polishing techniques such as mechanical polishing, chemical polishing, mechano-chemical polishing (combination of mechanical polishing and chemical polishing) or the like may be used. For example, it can be obtained by polishing by means of a fixed abrasive polisher (polishing liquid: water) to attain a roughness of #2000 or more, or can be obtained by a process in which, after lapping by a free abrasive lap (polisher: SiC paste or the like), lapping is conducted by using diamond paste as a polisher instead of the SiC paste. There are no specific restrictions on these polishing methods.

It is preferable to finish the surface of the target material by means of a #200 to #10,000 diamond wheel, particularly preferably by means of a #400 to #5,000 diamond wheel. If a diamond wheel with a mesh size of #200 or more or a diamond wheel with a mesh size of #10,000 or less is used, the target material can be prevented from being broken.

It is preferred that the surface roughness Ra of the target material be 0.5 μm or less and that the grinding surface have no directivity. If Ra is 0.5 μm or less, the grinding surface has no directivity, occurrence of abnormal discharge or generation of particles can be prevented.

Finally, the target material obtained is subjected to a cleaning treatment. For cleaning, air blowing, washing with running water or the like can be used. When foreign matters are removed by air blowing, foreign matters can be removed more effectively by air intake by means of a dust collector from the side opposite to the nozzle.

Since the above-mentioned air blow or washing with running water has its limit, ultrasonic cleaning or the like can also be conducted. In ultrasonic cleaning, it is effective to conduct by multiplex oscillation within a frequency range of 25 to 300 KHz. For example, it is preferable to perform ultrasonic cleaning by subjecting 12 kinds of frequency composed of every 25 KHz in a frequency range of 25 to 300 KHz to multiplex oscillation.

The thickness of the target material is normally 2 to 20 mm, preferably 3 to 12 mm, and particularly preferably 4 to 6 mm.

By bonding the target material obtained in the manner as mentioned above to a backing plate, a sputtering target can be obtained. A plurality of target materials may be provided in a single backing plate to be used as a substantially single target.

The sputtering target of the invention can have a relative density of 98% or more and a bulk resistance of 5 mΩcm or less by the above-mentioned production method. When sputtering is conducted, occurrence of abnormal discharge can be suppressed. The sputtering target of the invention can form a high-quality oxide semiconductor thin film efficiently and inexpensively and in an energy-saving manner.

### [Oxide Semiconductor Thin Film]

By forming a film with the use of the sputtering target of the invention by a sputtering method, the oxide semiconductor thin film of the invention can be obtained.

The oxide semiconductor thin film of the invention is composed of indium, tin, zinc, aluminum and oxygen and preferably satisfies the following atomic ratios (1) to (4):

0.08≦In/(In+Sn+Zn+Al)≦0.50 (1)

0.01≦Sn/(In+Sn+Zn+Al)≦0.30 (2)

0.30≦Zn/(In+Sn+Zn+Al)≦0.90 (3)

0.01≦Al/(In+Sn+Zn+Al)≦0.30 (4)

wherein In, Sn, Zn and Al are respectively an atomic ratio of the indium element, the tin element, the zinc element and the aluminum element in the oxide semiconductor thin film.

In the formula (1), if the atomic ratio of the In element is less than 0.08, the degree of overlapping of the In 5 s orbital may become small, and as a result, the field effect mobility may be less than 15 cm²/Vs. On the other hand, if the atomic ratio of the In element exceeds 0.50, reliability may be deteriorated if the formed film is applied to a channel layer of a TFT.

In the formula (2), if the atomic ratio of the Sn element is less than 0.01, the target resistance is increased, and film formation may not be stabilized due to occurrence of abnormal discharge during sputtering. On the other hand, if the atomic ratio of the Sn element exceeds 0.30, the solubility of the resulting thin film in a wet etchant is lowered, whereby wet etching may become difficult.

In the formula (3), if the atomic ratio of the Zn element is less than 0.30, the resulting film may not be a stable amorphous film. On the other hand, if the atomic ratio of the Zn element exceeds 0.90, the dissolution speed of the resulting thin film in a wet etchant is too high, resulting in difficulty in wet etching.

In the formula (4), if the atomic ratio of the Al element is less than 0.01, the oxygen partial pressure during film formation may be increased. Since the Al element is bonded to oxygen strongly, it can lower the oxygen partial pressure during film formation. Further, when a channel layer is formed and applied to a TFT, reliability may be lowered. On the other hand, if the atomic ratio of the Al element exceeds 0.30, Al₂O₃ may be generated in the target, abnormal discharge may occur at the time of film formation by sputtering, leading to unstable film formation.

The carrier concentration of the oxide semiconductor thin film is normally 10¹⁹/cm³ or less, preferably 10¹³ to 10¹⁸/cm³, further preferably 10¹⁴ to 10¹⁸/cm³, and particularly preferably 10¹⁵ to 10¹⁸/cm³.

If the carrier concentration of the oxide layer is 10¹⁹ cm⁻³ or less, it is possible to prevent current leakage, normally-on, lowering in on-off ratio when a device such as a thin film transistor is fabricated. As a result, good transistor performance may be exhibited. Further, if the carrier concentration is 10¹³ cm⁻³ or more, the device can be driven as a TFT without causing problems.

The carrier concentration of the oxide semiconductor thin film can be measured by the Hall effect measurement.

Due to a high conductivity, a DC sputtering method having a high film-forming speed can be applied to the sputtering target of the invention.

In addition to the above-mentioned DC sputtering method, the RF sputtering method, the AC sputtering method and the pulse DC sputtering method can be applied to the sputtering target of the invention, and sputtering free from abnormal discharge can be conducted.

The oxide semiconductor thin film can also be formed by using the above-mentioned sintered body by the deposition method, in addition to the sputtering method, the ion-plating method, the pulse laser deposition method or the like.

As the sputtering gas (atmosphere), a mixed gas of a rare gas atom such as argon and an oxidizing gas can be used. Examples of the oxidizing gas include O₂, CO₂, O₃, H₂O and N₂O. As the sputtering gas, a mixed gas containing a rare gas atom, and one or more molecules selected from a water molecule, an oxygen molecule and a nitrous oxide molecule is preferable. A mixed gas containing a rare gas atom and at least a water molecule is more preferable.

The oxygen partial pressure ratio at the time of film formation by sputtering is preferably 0% or more and less than 40%. A thin film formed under the conditions in which the oxygen partial pressure ratio is less than 40% may not have a significantly decreased carrier concentration. As a result, it becomes possible to prevent the carrier concentration from being less than 10¹³ cm⁻³.

The oxygen partial pressure ratio is preferably 0% to 30% and particularly preferably 0% to 20%.

The partial pressure ratio of water molecules contained in a sputtering gas (atmosphere) at the time of depositing an oxide thin film in the invention, i.e. [H₂O]/([H₂O]+[rare gas]+[other molecules]), is preferably 0.1 to 25%.

If the water partial pressure is 25% or less, it is possible to prevent a decrease in film density, and as a result, the degree of overlapping of the In 5 s orbital can be kept large, and as a result, lowering in mobility can be prevented.

The partial pressure ratio of water in the atmosphere at the time of sputtering is more preferably 0.7 to 13%, with 1 to 6% being particularly preferable.

The substrate temperature at the time of film formation by sputtering is preferably 25 to 120° C., further preferably 25 to 100° C., and particularly preferably 25 to 90° C.

If the substrate temperature at the time of film formation is 120° C. or less, oxygen or the like can be incorporated sufficiently at the time of film formation, whereby an excessive increase in carrier concentration of the thin film after heating can be prevented. Further, if the substrate temperature at the time of film formation is 25° C. or more, the density of the thin film may not be lowered, and as a result, lowering in mobility of a TFT can be prevented.

It is preferred that the oxide thin film obtained by sputtering be further subjected to an annealing treatment by retaining at 150 to 500° C. for 15 minutes to 5 hours. The annealing treatment temperature after film formation is more preferably 200° C. or more and 450° C. or less, further preferably 250° C. or more and 350° C. or less. By conducting the above-mentioned annealing treatment, semiconductor properties can be obtained.

The heating atmosphere is not particularly restricted. In respect of carrier control properties, the air atmosphere or the oxygen-circulating atmosphere is preferable.

In the annealing treatment as the post treatment of the oxide thin film, in the presence or absence of oxygen, a lamp annealing apparatus, a laser annealing apparatus, a thermal plasma apparatus, a hot air heating apparatus, a contact heating apparatus or the like can be used.

The distance between the target and the substrate at the time of sputtering is preferably 1 to 15 cm in a direction perpendicular to the deposition surface of the substrate, with 2 to 8 cm being further preferable.

If this distance is 1 cm or more, the kinetic energy of particles of target-constituting elements which arrive at the substrate can be prevented from becoming excessively large, good film properties can be obtained. Further, in-plane distribution or the like of the film thickness and the electric characteristics can be prevented. If the distance between the target and the substrate is 15 cm or less, the kinetic energy of particles of target-constituting elements can be prevented from becoming too small, and a dense film may be obtained, and as a result, good semiconductor properties can be obtained.

As for the formation of an oxide thin film, it is desirable that film formation be conducted by sputtering in an atmosphere having a magnetic field intensity of 300 to 1500 gausses. If the magnetic field intensity is 300 gausses or more, since lowering in plasma density can be prevented, sputtering can be conducted without problems even if the sputtering target has a high resistance. On the other hand, if the magnetic field intensity is 1500 gausses or less, deterioration in controllability of the film thickness and the electric characteristics of the film can be suppressed.

No specific restrictions are imposed on the pressure of a gas atmosphere (sputtering pressure), as long as plasma is stably discharged. The pressure is preferably 0.1 to 3.0 Pa, further preferably 0.1 to 1.5 Pa, with 0.1 to 1.0 Pa being particularly preferable.

If the sputtering pressure is 3.0 Pa or less, the mean free path of sputtering particles is not shortened excessively, thereby preventing lowering in density of a thin film. If the sputtering pressure is 0.1 Pa or more, fine crystals can be prevented from being formed in a film during film formation.

Meanwhile, the sputtering pressure is the total pressure in the system at the start of sputtering after rare gas atoms (e.g. argon), water molecules, oxygen molecules or the like are introduced.

The formation of an oxide semiconductor thin film may be conducted by the following AC sputtering.

Substrates are transported in sequence to positions opposing to 3 or more targets arranged in parallel with a prescribed interval in a vacuum chamber. Then, a negative potential and a positive potential are applied alternately from an AC power source to each of the targets, whereby plasma is caused to be generated on the target and a film is formed on the surface of the substrate.

At this time, film formation is conducted by applying at least one output from an AC power source between 2 or more targets connected divergently, while switching the target to which a potential is applied. That is, at least one output from the AC power source is connected divergently to 2 or more targets respectively, whereby film formation is conducted while applying different potentials to the adjacent targets.

If an oxide semiconductor thin film is formed by AC sputtering, it is preferred that sputtering be conducted in an atmosphere of a mixed gas containing a rare gas, and one or more gases selected from water vapor, an oxygen gas and a nitrous oxide gas, for example. It is particularly preferred that sputtering be conducted in an atmosphere of a mixed gas containing water vapor.

If film formation is conducted by AC sputtering, not only it is possible to obtain an oxide layer which has excellent large-area uniformity on the industrial basis, but also it can be expected that the use efficiency of the target is increased.

If a film is formed by sputtering on a large-area substrate in which the length of one side exceeds 1 m, it is preferable to use an AC sputtering apparatus for producing a large-area film such as that disclosed in JP-A-2005-290550.

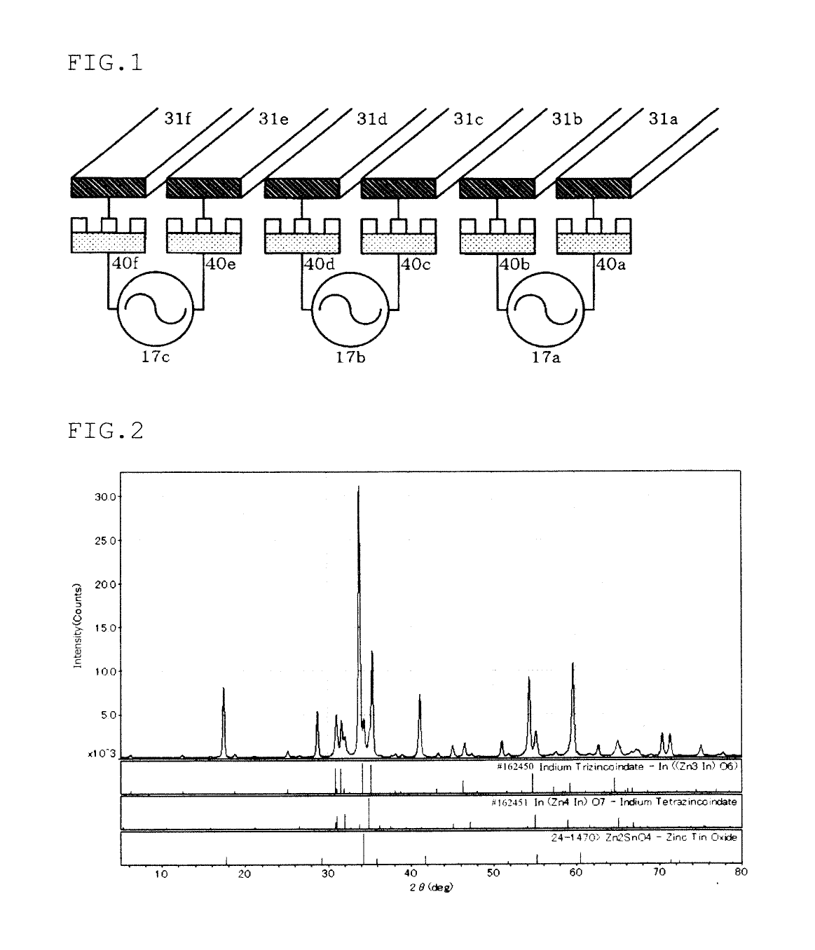

The AC sputtering apparatus disclosed in JP-A-2005-290550 specifically has a vacuum chamber, a substrate holder arranged within the vacuum chamber and a sputtering source arranged at a position opposing to this substrate holder. FIG. 1 shows essential parts of a sputtering source of the AC sputtering apparatus. The sputtering source has a plurality of sputtering parts, which respectively have plate-like targets 31a to 31f. Assuming that the surface to be sputtered of each target 31a to 31f is a sputtering surface, the sputtering parts are arranged such that the sputtering surfaces are on the same plane. Targets 31a to 31f are formed in a long and narrow form having a longitudinal direction, and they have the same shape. The targets are arranged such that the edge parts (side surface) in the longitudinal direction of the sputtering surface are arranged in parallel with a prescribed interval therebetween. Accordingly, the side surfaces of the adjacent targets 31a to 31f are in parallel.

Outside the vacuum chamber, AC power sources 17a to 17c are arranged. Among the two terminals of each of AC power sources 17a to 17c, one terminal is connected to one electrode of the adjacent two electrodes, and the other terminal is connected to the other electrode. The two terminals of each AC power source 17a to 17c output voltages differing in polarity (positive and negative), and the targets of 31a to 31f are fitted in close contact with the electrode, whereby, to adjacent two targets 31a to 31f, an alternate voltage differing in polarity is applied from the AC power sources 17a to 17c. Therefore, among the adjacent targets of 31a to 31f, if one is set in a positive potential, the other is set in a negative potential.

On the side opposite to the targets 31a to 31f of the electrode, magnetic field forming means 40a to 40f are arranged. Each magnetic field forming means 40a to 40f has a long and narrow ring-like magnet having an approximately same size as that of the outer circumference of the targets 31a to 31f, and a bar-like magnet which is shorter than the length of the ring-like magnet.

Each ring-like magnet is arranged at the position right behind one corresponding target 31a to 31f such that the ring-like magnets are arranged in parallel with the longitudinal direction of the targets 31a to 31f. As mentioned above, since the targets 31a to 31f are arranged in parallel with a prescribed interval therebetween, the ring-like magnets are arranged with the same interval as that for the targets 31a to 31f from each other.

The AC power density when an oxide target is used in AC sputtering is preferably 3 W/cm² or more and 20 W/cm² or less. If the power density is 3 W/cm² or more, the film-forming speed does not become too slow, and ensures economical advantage in respect of production. A power density of 20 W/cm² or less can prevent breakage of the target. A more preferable power density is 3 W/cm² to 15 W/cm².

The frequency of the AC sputtering is preferably in a range of 10 kHz to 1 MHz. If the frequency is 10 kHz or more, noise problems do not occur. If the frequency is 1 MHz or less, sputtering in other places than the desired target position due to excessively wide scattering of plasma can be prevented from being conducted, whereby uniformity can be kept. A more preferable AC sputtering frequency is 20 kHz to 500 kHz.

Conditions or the like at the time of sputtering other than those mentioned above may be appropriately selected from the conditions given above.

### [Thin Film Transistor and Display]

The above-mentioned oxide thin film can be used in a thin film transistor. It can be used particularly preferably as a channel layer. A thin film transistor using the oxide semiconductor thin film of the invention as a channel layer can exhibit a high mobility of a field effect mobility of 15 cm²Ns or more and a high reliability.

No specific restrictions are imposed on the device configuration of the thin film transistor of the invention, as long as it has the above-mentioned oxide thin film as a channel layer. Known various device configurations can be used.

The film thickness of the channel layer in the thin film transistor of the invention is normally 10 to 300 nm, preferably 20 to 250 nm, more preferably 30 to 200 nm, further preferably 35 to 120 nm, and particularly preferably 40 to 80 nm.

If the film thickness of the channel layer is 10 nm or more, the film thickness does not become un-uniform easily even when the film is formed to have a large area, the properties of a TFT fabricated may become uniform within the plane. If a film thickness is 300 nm or less, the film formation time can be prevented from being excessively prolonged.

The channel layer in the thin film transistor of the invention is normally used in the N-type region. However, in combination with various P-type semiconductors such as a P-type Si-based semiconductor, a P-type oxide semiconductor and a P-type organic semiconductor, the channel layer can be used in various semiconductor devices such as a PN junction transistor.

After annealing, the channel layer of the thin film transistor of the invention may be partially crystallized at least in a region overlapping the gate electrode. The “crystallized” means that crystal nucleus grows from the amorphous state or crystal particles are generated from the state in which crystal nucleus has been generated. In particular, when part of the back channel side is crystallized, reduction resistance relative to the plasma process (CVD process, or the like) is improved, whereby reliability of a TFT is increased.

The crystallized region can be confirmed by an electron diffraction image of a transmission electron microscope (TEM: Transmission Electron Microscope).

The oxide semiconductor thin film that is applied to the channel layer can be subjected to wet etching in an organic acid-based etching liquid (for example, oxalic acid-etching liquid), and is hardly dissolved in an inorganic acid-based wet etching liquid (for example, a mixed acid wet etching liquid of phosphoric acid/nitric acid/acetic acid: PAN). The selectivity of wet etching to Mo (molybdenum) or Al (aluminum) or the like used in the electrode is large. Therefore, by using the oxide thin film of the invention in a channel layer, a channel-etch type thin film transistor can be prepared.

In the photolithography process in which a semiconductor thin film is produced, before applying a photoresist, an insulating film with a thickness of several nm may be formed on the surface of an oxide semiconductor thin film. By this process, it is possible to eliminate direct contact of the oxide semiconductor film and the resist. As a result, it is possible to prevent impurities contained in the resist from entering the oxide semiconductor film.

In the thin film transistor of the invention, it is preferred that a protective film be provided on the channel layer. It is preferred that the protective film in the thin film transistor of the invention comprise at least SiNₓ. As compared with SiO₂, SiNₓ is capable of forming a dense film, and hence has an advantage that it has significant effects of preventing deterioration of a TFT.

The protective film may comprise, in addition to SiNₓ, an oxide such as SiO₂, Al₂O₃, Ta₂O₅, TiO₂, MgO, ZrO₂, CeO₂, K₂O, Li₂O, Na₂O, Rb₂O, Sc₂O₃, Y₂O₃, HfO₂, CaHfO₃, PbTiO₃, BaTa₂O₆, Sm₂O₃, SrTiO₃ or AlN.

As for the oxide thin film of the invention that comprises an indium element (In), a tin element (Sn), a zinc element (Zn) and an aluminum element (Al), since it contains Al, resistance to reduction by the CVD process is improved. As a result, the back channel side is hardly reduced by a process in which a protective film is prepared, whereby SiNₓ can be used as a protective film.

Before forming a protective film, it is preferred that the channel layer be subjected to an ozone treatment, an oxygen plasma treatment, a nitrogen dioxide plasma treatment or a nitrous oxide plasma treatment. Such a treatment may be conducted at any time as long as it is after the formation of a channel layer and before the formation of a protective film. However, it is desirable that the treatment be conducted immediately before the formation of a protective film. By conducting such a pre-treatment, generation of oxygen deficiency in the channel layer can be suppressed.

If hydrogen in the oxide semiconductor film diffuses during the driving of a TFT, the threshold voltage may be shifted, resulting in lowering of reliability of a TFT. By subjecting the channel layer to an ozone treatment, an oxygen plasma treatment or a nitrous oxide plasma treatment, the In—OH bonding in the thin film structure is stabilized, whereby diffusion of hydrogen in the oxide semiconductor film can be suppressed.

In the process of producing a thin-film transistor, in order to remove contamination by a metal such as Cu of a semiconductor substrate, as well as to decrease the surface potential caused by dangling bond or the like of the surface of a gate insulating film, it is preferred that the surface of the semiconductor substrate or the gate insulating film be cleaned.

As the cleaning solution used for the above-mentioned cleaning, a cyan (CN)-containing solution having a cyan (CN) content of 100 ppm or less, preferably with the upper limit being 10 ppm to 1 ppm and having a hydrogen ion concentration index (pH) of 9 to 14 can be used. It is preferred that the surface of the semiconductor substrate or the gate insulating film be subjected to a cleaning treatment using the cyan-containing solution heated to a temperature of 50° C. or less (preferably 30° C. to 40° C.).

By using a cyan-containing solution, for example, an aqueous HCN solution, cyanide ions (CN⁻) is reacted with copper on the surface of the substrate to form [Cu(CN)₂]⁻, whereby contaminated copper can be removed. [Cu(CN)₂]⁻ reacts with CN⁻ ions in an aqueous HCN solution, and at pH 10, it is present stably as [Cu(CN)₄]³⁻. The complex ion forming capability of CN⁻ ions is significantly large. Even in an aqueous solution of HCN having a very low concentration, CN⁻ ions effectively react, thereby enabling removal of contaminated copper.

As the cyan (CN)-containing solution used for cleaning, it is preferable to use the following. Hydrogen cyanide (HCN) is dissolved in water or ultrapure water, or at least one solvent selected from an alcohol-based solvent, a ketone-based solvent, a nitrile-based solvent, an aromatic hydrocarbon-based solvent, carbon tetrachloride, an ether-based solvent, an aliphatic alkane-based solvent or a mixed solvent of these. Further, the resulting solution is diluted to a predetermined concentration, followed by adjusting the hydrogen ion concentration index (the so-called pH value) in the solution with an ammonium aqueous solution or the like to a range of preferably 9 to 14.

The thin film transistor normally comprises a substrate, a gate electrode, a gate insulating layer, an organic semiconductor layer (channel layer), a source electrode and a drain electrode. The channel layer is as mentioned above. A known material can be used for the substrate.

No particular restrictions are imposed on the material forming the gate insulating film in the thin film transistor of the invention. A material which is generally used can be arbitrary selected. Specifically, a compound such as SiO₂, SiNₓ, Al₂O₃, Ta₂O₅, TiO₂, MgO, ZrO₂, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, AlN or the like can be used, for example. Among these, SiO₂, SiNₓ, Al₂O₃, Y₂O₃, HfO₂ and CaHfO₃ are preferable, with SiO₂, SiNₓ, HfO₂ and Al₂O₃ being more preferable.

The gate insulating film can be formed by the plasma CVD (Chemical Vapor Deposition) method, for example.

If a gate insulating film is formed by the plasma CVD method and a channel layer is formed thereon, hydrogen in the gate insulating film diffuses in the channel layer, and as a result, deterioration of film quality of the channel layer or lowering of reliability of a TFT may be caused. In order to prevent deterioration of film quality of the channel layer or lowering of reliability of a TFT, it is preferred that the gate insulating film be subjected to an ozone treatment, an oxygen plasma treatment, a nitrogen dioxide plasma treatment or a nitrous oxide plasma treatment before the formation of a channel layer. By conducting such a pre-treatment, deterioration of film quality of the channel layer or lowering of reliability of a TFT can be prevented.

The number of oxygen atoms of these oxides does not necessarily coincide with the stoichiometric ratio. For example, SiO₂ or SiOₓ may be used.

The gate insulting film may have a structure in which two or more insulating films formed of different materials are stacked. The gate insulating film may be crystalline, polycrystalline or amorphous. The gate insulating film is preferably polycrystalline or amorphous from the viewpoint of easiness of industrial production.

No specific restrictions are imposed on the material forming each electrode in the thin film transistor of the invention, i.e. a drain electrode, a source electrode and a gate electrode, and materials which are generally used can be arbitrarily selected. For example, transparent electrodes such as ITO, IZO, ZnO, SnO₂ or the like, a metal electrode such as Al, Ag, Cu, Cr, Ni, Mo, Au, Ti, and Ta or an alloy metal electrode containing these metals can be used.

Each of the drain electrode, the source electrode and the gate electrode may have a multi-layer structure in which two or more different conductive layers are stacked. In particular, since the source/drain electrodes are required to be used in low-resistance wiring, the electrodes may be used by sandwiching a good conductor such as Al and Cu between metals having good adhesiveness such as Ti and Mo.

In the thin film transistor of the invention, the S value is preferably 0.8 V/dec or less, more preferably 0.5 V/dec or less, further preferably 0.3 V/dec or less, and 0.2 V/dec or less is particularly preferable. If the S value is 0.8 V/dec or less, the driving voltage is reduced, and consumption power may be able to be reduced. In particular, if the thin film transistor is used in an organic EL display, since it is driven by DC driving, it is preferable to allow the S value to be 0.3 V/dec or less in view of a significant decrease in consumption power.

The S value can be derived from a reciprocal of the slope of a graph of Log(Id)-Vg obtained from the results of transfer characteristics. The unit of the S value is V/decade, and a smaller S value is preferable.

The S value (Swing Factor) is a value indicating the sharpness of rising of the drain current from the off-state to the on-state when the gate voltage of a transistor is increased from the off-state. Specifically, the S value is defined by the following formula. As defined by the following formula, the S value is an increase in gate voltage when the drain current increases by one digit (10 times).

S value=dVg/d log(Ids)

When the S value is small, the rising of the drain current is sharp (“Thin Film Transistor Technology”, by Ukai Yasuhiro, 2007, published by Kogyo Chosakai Publishing, Inc.). If the S value is large, there may be a possibility that a high gate voltage is required to be applied at the time of switching from ON to OFF, resulting in large consumption power.

The thin film transistor of the invention can be applied to various integrated circuits such as a field effect transistor, a logical circuit, a memory circuit and a differential amplifier circuit. Further, in addition to a field effect transistor, it can be applied to a static induction transistor, a Schottky barrier transistor, a Schottky diode and a resistance element.

As for the configuration of the thin film transistor of the invention, a known configuration such as a bottom-gate configuration, a bottom-contact configuration and a top-contact configuration can be used without restrictions.

In particular, a bottom-gate configuration is advantageous since high performance can be obtained as compared with a thin film transistor comprising amorphous silicon or ZnO. The bottom-gate configuration is preferable since the number of masks at the time of production can be decreased easily and the production cost for application such as a large-sized display or the like can be reduced easily.

The thin film transistor of the invention can preferably be used as a display.

For use in a large-sized display, a channel-etch type bottom-gate thin film transistor is particularly preferable. A channel-etch type bottom-gate thin film transistor can produce a panel for a display at a low cost since the number of photo-masks used in photolithography is small. Among these, a channel-etch type thin film transistor having a bottom-gate configuration and a channel-etch type thin film transistor having a top-contact configuration are particularly preferable since they have excellent properties such as mobility and can be industrialized easily.

### EXAMPLES

### Examples 1 to 7

### Production of Oxide Sintered Body

As raw material powders, the following oxide powders were used. The median size D50 was employed as an average particle size for the following oxide powders. The average particle size was measured by a laser diffraction particle size analyzer SALD-300V (manufactured by Shimadzu Corporation).

Indium oxide powder: average particle size 0.98 μm

Tin oxide powder: average particle size 0.98 μm

Zinc oxide powder: average particle size 0.96 μm

Aluminum oxide powder: average particle size 0.98 μm

The above-mentioned powders were weighed such that the atomic ratio shown in Table 1 was attained. They were finely pulverized and mixed uniformly and then granulated by adding a binder for forming. Subsequently, the mixed powder of the raw materials was filled in the mold uniformly and press-formed at a pressing pressure of 140 MPa in a cold press apparatus.

The formed body obtained was sintered in a sintering furnace at a temperature-elevating speed, a sintering temperature and a sintering time shown in Table 1 to produce a sintered body. During the temperature elevation, the atmosphere was oxide, and otherwise air (atmosphere). The temperature-decreasing speed was 15° C./min.

### [Analysis of Sintered Body]

The relative density of the sintered body obtained was measured by the Archimedean method. The sintered bodies of Examples 1 to 7 were confirmed to have a relative density of 98% or more.

Further, the bulk specific resistance (conductivity) of the sintered body obtained was measured by means of a resistivity meter (Loresta, manufactured by Mitsubishi Chemical Analytech Co., Ltd.) in accordance with the four point probe method (JIS R 1637). The results are shown in Table 2. As shown in Table 2, the bulk specific resistances of the sintered bodies of Examples 1 to 7 were 5 mΩcm or less.

For the sintered body obtained, ICP-AES analysis was conducted. As a result, it was confirmed to have the atomic ratio shown in Table 1.

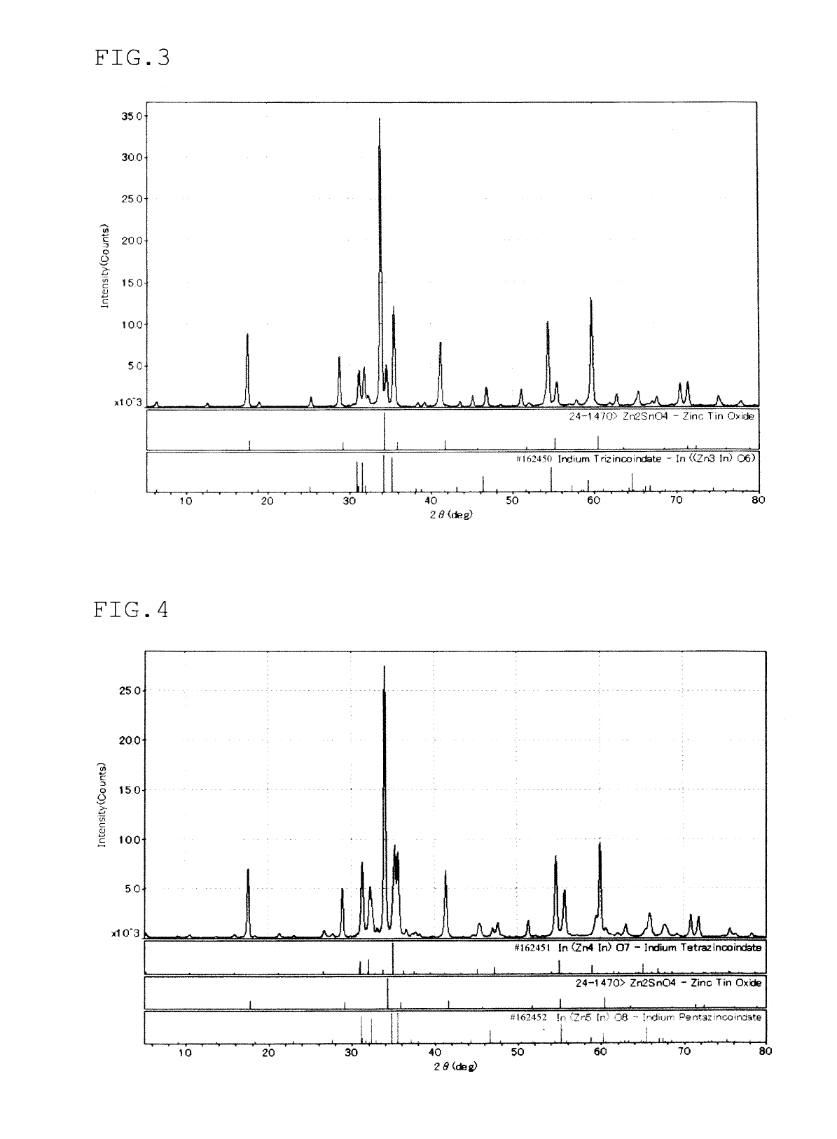

Moreover, the crystal structure of the sintered body obtained was determined by means of an X-ray diffraction (XRD) apparatus. X-ray diffraction charts of the sintered bodies obtained in Examples 1 to 3 are shown in FIGS. 2 to 4, respectively.

As a result of analyzing the chart, a homologous structure of In₂Zn₃O₆, a homologous structure of In₂Zn₄O₇ and a spinel structure of Zn₂SnO₄ were observed in the sintered body of Example 1. The crystal structure can be confirmed by using JCPDS cards and/or ICSD.

The homologous structure represented by In₂Zn₃O₆ can be retrieved from ICSD database by X-ray diffraction, and shows a peak pattern of ICSD #162450. The homologous structure represented by In₂Zn₄O₇ can be retrieved from ICSD database by X-ray diffraction, and shows a peak pattern of ICSD #162451. The spinel structure compound represented by Zn₂SnO₄ shows a peak pattern of No. 24-1470 of the JCPDS database.

As a result of the calculation of the lattice constant of the homologous structure represented by In₂Zn₃O₆, it was found that a=b=3.32724 Å and c=4227143 Å. Since the lattice constant disclosed in ICSD #162450 database is a=b=3.3520 Å and c=42.488 Å, it was confirmed that the lattice constant became small in the sintered bodies in the Examples. Since the ionic radius of Al³⁺ is smaller than the ionic radius of In³⁺, Al is in the solid-solution state in the homologous structure represented by In₂Zn₃O₆, and hence the lattice constant becomes small.

As a result of the calculation of the lattice constant of the homologous structure represented by In₂Zn₄O₇, it was found that a=b=3.32187 Å and c=33.39592 Å. Since the lattice constant disclosed in ICSD #162451 database is a=b=3.3362 Å and c=33.526 Å, it was confirmed that the lattice constant became small in the sintered bodies in the Examples. Since the ionic radius of Al³⁺ is smaller than the ionic radius of In³⁺, Al is in the solid-solution state in the homologous structure represented by In₂Zn₄O₇, and hence the lattice constant becomes small.

In the same manner as in Example 1, an XRD measurement was conducted in the sintered bodies in Examples 2 to 7. As a result, it was found that the sintered bodies of Examples 2 to 7 contained a homologous structure compound represented by In₂O₃(ZnO)ₙ (n is 2 to 20) and a spinel structure compound represented by Zn₂SnO₄. The lattice constant of the homologous structure represented by In₂O₃(ZnO)ₙ (n is 2 to 20) is shown in Table 1. As shown in Table 1, also in Examples 2 to 7, it was confirmed that the lattice constant of In₂O₃(ZnO)ₙ (n is 2 to 20) is smaller than the lattice constant disclosed in the ICSD database.

XRD was measured under the following conditions.
Apparatus: Ultima-III manufactured by Rigaku Corporation
X ray: Cu—Kα rays (wavelength 1.5406 Å, monochromatized with a graphite monochromator)
2θ-θ reflection method, continuous scanning (1.0°/min)
sampling interval: 0.02°
slits DS, SS: 2/3°, RS: 0.6 mm

For the sintered bodies of Examples 1 to 7, the dispersion of Sn or Al in the sintered body obtained by the electron probe microanalyzer (EPMA) measurement was checked. 8 μm or larger-sized aggregation of Sn or Al was not observed. As a result, the sintered bodies of Examples 1 to 7 were found to be significantly excellent in dispersivity and homogeneousness.

The EPMA measurement was conducted under the following conditions.

Apparatus: JXA-8200 (JEOL Ltd.)

Accelerating voltage: 15 kV

Irradiation current: 50 nA

Irradiation time (per one point): 50 mS

### [Production of Sputtering Target]

The surface of the sintered bodies obtained in Examples 1 to 7 was ground by means of a surface grinder. The sides thereof were cut using a diamond cutter. The sintered bodies were bonded to a backing plate, thereby to obtain sputtering targets each having a diameter of 4 inches. Further, in Examples 1 to 3, 6 targets each having a width of 200 mm, a length of 1700 mm and a thickness of 10 mm were fabricated for AC sputtering film-forming.

### [Confirmation of Presence or Absence of Abnormal Discharge]

A sputtering target having a diameter of 4 inches obtained was mounted in a DC sputtering apparatus. As the atmosphere, a mixed gas obtained by adding a H₂O gas to an argon gas at a partial pressure ratio of 2% was used. A 10 kWh continuous sputtering was conducted at a DC power of 400 W with the sputtering pressure being 0.4 Pa and the substrate temperature being room temperature. Variations in voltage during the sputtering were stored in data logger to confirm the presence or absence of abnormal discharge. The results are shown in Table 2.

The above-mentioned presence or absence of abnormal discharge was determined by detecting abnormal discharge while monitoring variations in voltage. Specifically, “abnormal discharge” is defined by the case where the voltage variation generated for a measurement time of 5 minutes is 10% or more of the working voltage during sputtering operation. In particular, when the working voltage during a sputtering operation varies within a range of ±10% for 0.1 second, micro arcs, which are abnormal discharge during sputtering, may generate, thereby lowering the yield of a device. Accordingly, they may be unsuitable for mass production.

### [Confirmation of Presence or Absence of Nodule Generation]

Sputtering was conducted continuously for 40 hours by using a 4-inch-diameter sputtering target obtained with the atmosphere being a mixed gas obtained by adding a hydrogen gas to an argon gas at a partial pressure ratio of 3% to confirm the presence or absence of nodule generation. As a result, on the surface of sputtering targets of Examples 1 to 7, no nodules were observed.

The conditions at the time of the sputtering include a sputtering pressure of 0.4 Pa, a DC power of 100 W and a substrate temperature of room temperature. The hydrogen gas was added to the atmosphere gas in order to promote nodule generation.

For evaluation of nodules, the following method was employed. The change in the target surface after sputtering was observed at a magnification of 50 times by means of a stereomicroscope. The number average of nodules having a size of 20 μm or larger generated in the visual field of 3 mm² was calculated. Table 2 shows the number of nodules generated.

### Comparative Examples 1 and 2

Sintered bodies and sputtering targets were produced and evaluated in the same manner as in Examples 1 to 7, except that the raw material powders were mixed according to the atomic ratio shown in Table 1, and sintered at a temperature-elevating speed, at a sintering temperature and for a sintering time as shown in Table 1. The results are shown in Tables 1 and 2.

In the sputtering targets of Comparative Examples 1 and 2, abnormal discharge occurred during sputtering and nodules were observed on the surface of the target. In the targets of Comparative Examples 1 and 2, a homologous structure represented by InAlZn₂O₅, a spinel structure represented by Zn₂SnO₄ and a corundum structure represented by Al₂O₃ were observed. The homologous structure of InAlZn₂O₅ can be confirmed by No. 40-0259 of the JCPDS card and the corundum structure of Al₂O₃ can be confirmed by No. 10-173 of the JCPDS card.

In the targets of Comparative Examples 1 and 2, since Al₂O₃ is present in the target, the relative density of the target was less than 98%, and the bulk specific resistance of the target exceeded 5 mΩcm.

TABLE 1

| | | | | | First | Second | Third | | | | | | |
|---|---|---|---|---|---|---|---|---|---|---|---|---|---|
| | In/ | Sn/ | Zn/ | Al/ | temper- | temper- | temper- | | Maximum | | | | |
| | (In + | (In + | (In + | (In + | ature- | ature- | ature- | | temper- | | | | |
| | Sn + | Sn + | Sn + | Sn + | elevat- | elevat- | elevat- | | ature- | | Lattice | Lattice | Lattice |
| | Zn + | Zn + | Zn + | Zn + | ing | ing | ing | Maximum | retain- | | constant | constant | constant |
| | Al) | Al) | Al) | Al) | speed | speed | speed | temper- | ing | | of | of | of |
| | [Atomic | [Atomic | [Atomic | [Atomic | [° C./ | [° C./ | [° C./ | ature | time | Generated | In₂Zn₃O₆ | In₂Zn₄O₇ | In₂Zn₅O₈ |
| | ratio] | ratio] | ratio] | ratio] | min] | min] | min] | [° C.] | [hr] | compounds | [Å] | [Å] | [Å] |
| Exam- | 0.25 | 0.15 | 0.59 | 0.01 | 1.2 | 0.6 | 0.2 | 1400 | 20 | In₂Zn₃O₆ | a = b = | a = b = | |
| ple 1 | | | | | | | | | | In₂Zn₄O₇ | 3.32724 | 3.32187 | |
| | | | | | | | | | | Zn₂SnO₄ | c = | c = | |
| | | | | | | | | | | | 42.27143 | 33.39592 | |
| Exam- | 0.25 | 0.15 | 0.57 | 0.03 | 1.0 | 0.6 | 0.2 | 1400 | 20 | In₂Zn₃O₆ | a = b = | | |
| ple 2 | | | | | | | | | | Zn₂SnO₄ | 3.3104 | | |
| | | | | | | | | | | | c = | | |
| | | | | | | | | | | | 42.0838 | | |
| Exam- | 0.15 | 0.15 | 0.67 | 0.03 | 0.6 | 0.4 | 0.2 | 1400 | 20 | In₂Zn₄O₇ | | a = b = | a = b = |
| ple 3 | | | | | | | | | | In₂Zn₅O₈ | | 3.29649 | 3.29337 |
| | | | | | | | | | | Zn₂SnO₄ | | c = | c = |
| | | | | | | | | | | | | 33.25052 | 57.66555 |
| Exam- | 0.30 | 0.10 | 0.59 | 0.01 | 1.2 | 0.6 | 0.2 | 1400 | 20 | In₂Zn₃O₆ | a = b = | a = b = | |
| ple 4 | | | | | | | | | | In₂Zn₄O₇ | 3.32885 | 3.32286 | |
| | | | | | | | | | | Zn₂SnO₄ | c = | c = | |
| | | | | | | | | | | | 42.30201 | 33.39613 | |
| Exam- | 0.30 | 0.10 | 0.57 | 0.03 | 1.2 | 0.6 | 0.2 | 1400 | 20 | In₂Zn₃O₆ | a = b = | a = b = | |
| ple 5 | | | | | | | | | | In₂Zn₄O₇ | 3.31834 | 3.31972 | |
| | | | | | | | | | | Zn₂SnO₄ | c = | c = | |
| | | | | | | | | | | | 42.15326 | 33.32065 | |
| Exam- | 0.20 | 0.15 | 0.64 | 0.01 | 0.6 | 0.4 | 0.2 | 1400 | 15 | In₂Zn₃O₆ | a = b = | a = b = | |
| ple 6 | | | | | | | | | | In₂Zn₄O₇ | 3.31391 | 3.31098 | |
| | | | | | | | | | | Zn₂SnO₄ | c = | c = | |
| | | | | | | | | | | | 42.17095 | 33.36708 | |
| Exam- | 0.20 | 0.15 | 0.62 | 0.03 | 0.6 | 0.4 | 0.2 | 1400 | 15 | In₂Zn₃O₆ | a = b = | a = b = | |
| ple 7 | | | | | | | | | | In₂Zn₄O₇ | 3.30217 | 3.30522 | |
| | | | | | | | | | | Zn₂SnO₄ | c = | c = | |
| | | | | | | | | | | | 42.12904 | 33.30914 | |
| Comp. | 0.20 | 0.10 | 0.20 | 0.50 | 8.0 | 3.0 | 3.0 | 1150 | 8 | InAlZn₂O₅ | | | |
| Ex. 1 | | | | | | | | | | Zn₂SnO₄ | | | |
| | | | | | | | | | | Al₂O₃ | | | |
| Comp. | 0.15 | 0.20 | 0.15 | 0.50 | 8.0 | 3.0 | 3.0 | 1150 | 8 | InAlZn₂O₆ | | | |
| Ex. 2 | | | | | | | | | | Zn₂SnO₄ | | | |
| | | | | | | | | | | Al₂O₃ | | | |

The first temperature-elevating speed means an average temperature-elevating speed at 400° C. or higher and lower than 700° C.
The second temperature-elevating speed means an average temperature-elevating speed at 700° C. or higher and lower than 1100° C.
The third temperature-elevating speed means an average temperature-elevating speed at 1100° C. or higehr and 1400° C. or less.

TABLE 2

| | | | | Number of |
|---|---|---|---|---|
| | Target | Bulk | Presence or absence | generated |
| | relataive | specific | of abnormal | nodules |
| | density | resistance | discharge during | [number/ |
| | [%] | [mΩcm] | sputtering | 3 mm²] |
| Example 1 | 99.8 | 1.5 | None | 0 |
| Example 2 | 99.8 | 1.3 | None | 0 |
| Example 3 | 99.5 | 1.8 | None | 0 |
| Example 4 | 99.5 | 2.3 | None | 0 |
| Example 5 | 99.8 | 1.1 | None | 0 |
| Example 6 | 99.9 | 1.8 | None | 0 |
| Example 7 | 99.7 | 1.5 | None | 0 |
| Comp. Ex. 1 | 90.2 | 38.2 | Micro arc generated | 25 |
| Comp. Ex. 2 | 93.7 | 35.9 | Micro arc generated | 18 |

### Examples 8 to 14

### Formation of Oxide Semiconductor Thin Film

The 4-inch targets produced in Examples 1 to 7 and having the compositions shown in Tables 3 and 4 were mounted in a magnetron sputtering apparatus, and slide glass (#1737, manufactured by Corning Inc.) was installed as a substrate in each case. By the DC magnetron sputtering method, a 50 nm-thick amorphous film was formed on the slide glass under the following conditions.

At the time of film formation, an Ar gas, an O₂ gas and a H₂O gas were introduced at partial pressure ratios (%) shown in Tables 3 and 4. The substrate on which an amorphous film was formed was heated in an atmosphere at 300° C. for 60 minutes, whereby an oxide semiconductor thin film was formed.

Sputtering conditions were as follows.

Substrate temperature: 25° C.

Ultimate pressure: 8.5×10⁻⁵ Pa

Atmospheric gas: Ar gas, O₂ gas, H₂O gas (for partial pressure, see Tables 3 and 4)

Sputtering pressure (total pressure): 0.4 Pa

Input power: DC 100 W

S (substrate)−T (target) distance: 70 mm

### [Evaluation of Oxide Semiconductor Thin Film]

A glass substrate on which an oxide semiconductor film was formed was set in a Resi Test 8300 (manufactured by TOYO Corporation), and the Hall effect was evaluated at room temperature. Further, by the ICP-AES analysis, it was confirmed that the atomic ratio of each element contained in the oxide thin film was the same as that of the sputtering target.

The crystal structure of the oxide thin film formed on the glass substrate was examined by means of an X-ray diffraction measurement apparatus (Ultima-III, manufactured by Rigaku Corporation).

In Examples 8 to 14, no diffraction peaks were observed immediately after the deposition of the thin film, and hence it was confirmed that the thin film was amorphous. After conducting a heat treatment (annealing) in the air at 300° C. for 60 minutes, no diffraction peaks were observed, and the thin film was confirmed to be amorphous.

The measuring conditions of the XRD are as follows.

Apparatus: Ultima-III, manufactured by Rigaku Corporation

X ray: Cu—Kα rays (wavelength: 1.5406 Å, monochromatized by means of a graphite monochrometer)

2θ-θ reflection method, continuous scanning (1.0°/min)

Sampling interval: 0.02°

Slit DS, SS: 2/3°, RS: 0.6 mm

### [Production of Thin Film Transistor]

As a substrate, a conductive silicon substrate provided with a 100 nm-thick thermally oxidized film was used. The thermally oxidized film functioned as a gate insulating film and the conductive silicon part functioned as a gate electrode.

On the gate insulating film, a film was formed by sputtering under the conditions shown in Tables 3 and 4, whereby a 50 nm-thick amorphous thin film was fabricated. As a resist, OFPR#800 (manufactured by Tokyo Ohka Kogyo Co., Ltd.) was used. Coating, pre-baking (80° C., 5 minutes) and exposure were conducted. After development, post-baking (120° C., 5 minutes), etching with oxalic acid, and patterning into a desired shape were conducted. Thereafter, the film was subjected to a heat treatment at 300° C. for 60 minutes in a hot-air oven (annealing treatment).

Thereafter, Mo (100 nm) was formed into a film by sputtering, and source/drain electrodes were patterned by the lift-off method in a desired shape. As shown in Tables 3 and 4, as a pre-treatment before forming a protective film, an oxide semiconductor film was subjected to a nitrous oxide plasma treatment. Further, SiOₓ was formed into a film by the plasma CVD (PECVD) method to obtain a protective film. A contact hole was formed by using hydrofluoric acid, whereby a thin film transistor was fabricated.

For the thus fabricated thin film transistor, a field effect mobility (p), an S value and a threshold voltage (Vth) were evaluated. The results are shown in Tables 3 and 4.

These characteristic values were measured by using a semiconductor parameter analyzer (4200SCS, manufactured by Keithley Instruments, Inc.) at room temperature in a light-shielding environment (in a shield box).

For the produced transistor, transfer characteristics were evaluated with the drain voltage (Vd) and the gate voltage (Vg) being 1V and −15 to 20V, respectively. The results are shown in Tables 3 and 4.

The field effect mobility (μ) was calculated from the linear mobility, and defined as the maximum value of Vg-μ.

For the fabricated thin film transistor, a DC bias stress test was conducted. Tables 3 and 4 show a change in TFT transfer characteristics before and after application of a DC stress of Vg=15V and Vd=15V (stress temperature: 80° C. or less) for 10000 seconds.

It was revealed that the thin film transistor in Examples 8 to 14 suffered only a slight change in threshold voltage, i.e. it was hardly affected by a DC stress.

### Comparative Examples 3 and 4

By using the 4-inch targets fabricated in Comparative Examples 1 and 2, oxide semiconductor thin films, devices for evaluating the thin films and thin film transistors were fabricated and evaluated in the same manner as in Examples 8 to 14 in accordance with the sputtering conditions, heating (annealing) conditions and a pre-treatment for forming a protective film shown in Table 3. In Comparative Examples 3 and 4, a SiOₓ film was formed on the oxide semiconductor film in a thickness of 100 nm by the PECVD method without conducting a pre-treatment such as a nitrous oxide plasma treatment, and further, on the SiOₓ film, a SiNₓ film was formed in a thickness of 150 nm. A stacked body of the SiOₓ film and the SiNₓ film was allowed to be a protective film. The results are shown in Tables 3 and 4.

As shown in Tables 3 and 4, the devices in Comparative Examples 3 and 4 had a field effect mobility of less than 15 cm²/Vs that was significantly lower than those of the devices in Examples 8 to 14. As a result of a DC bias stress test, in the thin film transistors of Comparative Examples 3 and 4, the threshold voltage varied by 1V or more, revealing that significant deterioration in characteristics occurred.

TABLE 3

| | | Example 8 | Example 9 | Example 10 | Example 11 | Example 12 |
|---|---|---|---|---|---|---|
| Target composition | | In/(In + Sn + | In/(In + Sn + | In/(In + Sn + | In/(In + Sn + | In/(In + Sn + |
| | | Zn + Al) = 0.25 | Zn + Al) = 0.25 | Zn + Al) = 0.15 | Zn + Al) = 0.30 | Zn + Al) = 0.30 |
| | | Sn/(In + Sn + | Sn/(In + Sn + | Sn/(In + Sn + | Sn/(In + Sn + | Sn/(In + Sn + |
| | | Zn + Al) = 0.15 | Zn + Al) = 0.15 | Zn + Al) = 0.15 | Zn + Al) = 0.10 | Zn + Al) = 0.10 |
| | | Zn/(In + Sn + | Zn/(In + Sn + | Zn/(In + Sn + | Zn/(In + Sn + | Zn/(In + Sn + |
| | | Zn + Al) = 0.59 | Zn + Al) = 0.57 | Zn + Al) = 0.67 | Zn + Al) = 0.59 | Zn + Al) = 0.57 |
| | | Al/(In + Sn + | Al/(In + Sn + | Al/(In + Sn + | Al/(In + Sn + | Al/(In + Sn + |
| | | Zn + Al) = 0.01 | Zn + Al) = 0.03 | Zn + Al) = 0.03 | Zn + Al) = 0.01 | Zn + Al) = 0.03 |
| Sputtering | Ultimate pressure (Pa) | 8.5 × 10⁻⁵ | 8.5 × 10⁻⁵ | 8.5 × 10⁻⁵ | 8.5 × 10⁻⁵ | 8.5 × 10⁻⁵ |
| conditions | Sputtering pressure (Pa) | 0.4 | 0.4 | 0.4 | 0.4 | 0.4 |
| | [H₂O]/([H₂O] + [Ar] + [O₂])(%) | 0 | 1 | 0 | 1 | 1 |
| | [Ar]/([H₂O] + [Ar] + [O₂])(%) | 95 | 94 | 95 | 94 | 94 |
| | [O₂]/([H₂O] + [Ar] + [O₂])(%) | 5 | 5 | 5 | 5 | 5 |
| | Water partial pressure (Pa) | 0 | 4.0 × 10⁻³ | 0 | 4.0 × 10⁻³ | 4.0 × 10⁻³ |
| | Sputtering type | DC | DC | DC | DC | DC |
| | T-S distance (nm) | 70 | 70 | 70 | 70 | 70 |
| | Film thickness (nm) | 50 | 50 | 50 | 50 | 50 |
| | Substrate temperature (° C.) | 25 | 25 | 25 | 25 | 25 |
| Annealing | Annealing temperature (° C.) | 300 | 300 | 300 | 300 | 300 |
| | Annealing time (min) | 60 | 60 | 60 | 60 | 60 |
| | Atmosphere | Air | Air | Air | Air | Air |
| Hall | Hall mobility (cm²/Vs) | 21 | 21 | 21 | 21 | 21 |
| measurement | Carrier concentration (cm⁻³) | 1.58 × 10¹⁷ | 8.29 × 10¹⁶ | 9.67 × 10¹⁷ | 2.58 × 10¹⁷ | 9.41 × 10¹⁶ |
| TFT | Channel width/Channel length (μm) | 20/10 | 20/10 | 20/10 | 20/10 | 20/10 |
| | Source/drain | Mo | Mo | Mo | Mo | Mo |
| | Source/drain patterning | Lift off | Lift off | Lift off | Lift off | Lift off |
| | Pre-treatment before abrasion | Nitrous oxide | Nitrous oxide | Nitrous oxide | Nitrous oxide | Nitrous oxide |
| | of protective film | plasma | plasma | plasma | plasma | plasma |
| | Protective film | SiOx | SiOx | SiOx | SiOx | SiOx |
| | Mobility (cm²/Vs) | 27.1 | 24.3 | 18.4 | 20.6 | 18.7 |
| | Threshold voltage Vth(V) | 1.3 | 1.9 | 1.5 | 0.43 | 1.3 |
| | S value (V/dec) | 0.13 | 0.12 | 0.12 | 0.19 | 0.13 |
| | Threshold voltage shift [symbol] Vth(V) | 0.17 | 0.15 | 0.16 | 0.26 | 0.15 |

TABLE 4

| | | Example 13 | Example 14 | Com. Ex. 3 | Com. Ex. 4 |
|---|---|---|---|---|---|
| Target composition | | In/(In + Sn + Zn + Al) = 0.20 | In/(In + Sn + Zn + | In/(In + Sn + | In/(In + Sn + |
| | | | Al) = 0.20 | Zn + Al) = 0.20 | Zn + Al) = 0.15 |
| | | Sn/(In + Sn + Zn + Al) = 0.15 | Sn/(In + Sn + Zn + | Sn/(In + Sn + | Sn/(In + Sn + |
| | | | Al) = 0.15 | Zn + Al) = 0.10 | Zn + Al) = 0.20 |
| | | Zn/(In + Sn + Zn + Al) = 0.64 | Zn/(In + Sn + Zn + | Zn/(In + Sn + | Zn/(In + Sn + |
| | | | Al) = 0.62 | Zn + Al) = 0.20 | Zn + Al) = 0.15 |
| | | Al/(In + Sn + Zn + Al) = 0.01 | Al/(In + Sn + Zn + | Al/(In + Sn + | Al/(In + Sn + |
| | | | Al) = 0.03 | Zn + Al) = 0.50 | Zn + Al) = 0.50 |
| Sputtering | Ultimate pressure (Pa) | 8.5 × 10⁻⁵ | 8.5 × 10⁻⁵ | 8.5 × 10⁻⁵ | 8.5 × 10⁻⁵ |
| conditions | Sputtering pressure (Pa) | 0.4 | 0.4 | 0.4 | 0.4 |
| | [H₂O]/([H₂O] + [Ar] + [O₂]) (%) | 0 | 0 | 0 | 0 |
| | [Ar]/([H₂O] + [Ar] + [O₂]) (%) | 85 | 90 | 50 | 50 |
| | [O₂]/([H₂O)] + [Ar] + [O₂]) (%) | 15 | 10 | 50 | 50 |
| | Water pressure (Pa) | 0 | 0 | 0 | 0 |
| | Sputtering method | DC | DC | DC | DC |
| | T-S distance (mm) | 70 | 70 | 70 | 70 |
| | Film thickness (nm) | 50 | 50 | 50 | 50 |
| | Substrate temperature (° C.) | 25 | 25 | 25 | 25 |
| Annealing | Annealing temperature (° C.) | 300 | 300 | 300 | 300 |
| | Annealing time (min) | 60 | 60 | 60 | 60 |
| | Atmosphere | Air | Air | Air | Air |
| Half measurement | Half mobility (cm²Vs) | 14 | 11 | 2.3 | 1.7 |
| TFT | Carrier concentration (cm⁻³) | 8.91 × 10¹⁶ | 7.03 × 10¹⁶ | 3.17 × 10¹⁵ | 9.38 × 10¹⁴ |
| | Channel width/Channel | 20/10 | 20/10 | 20/10 | 20/10 |
| | length (μm) | | | | |
| | Source/drain | Mo | Mo | Mo | Mo |
| | Souce/drain patterning | Lift-off | Lift-off | Lift-off | Lift-off |
| | Pre-treatment before | Nitrous oxide plasma | Nitrous oxide plasma | No treatment | No treatment |
| | formation of protective film | | | | |
| | Protective film | SiOx | SiOx | SiOx/SiNx | SiOx/SiNx |
| | Mobility (cm²/Vs) | 16.3 | 15.1 | 3.2 | 2.8 |
| | Threshold voltage Vth (V) | 3.8 | 2.9 | 6.8 | 7.6 |
| | S value (V/dec) | 0.18 | 0.14 | 0.45 | 0.48 |
| | Threshold voltage shift [symbol] Vth (V) | 0.11 | 0.11 | 3.6 | 3.7 |

### Examples 15 to 17

In accordance with the sputtering conditions and annealing conditions shown in Table 5, the oxide semiconductor and the thin film transistor were fabricated and evaluated in the same manner as in Examples 8 to 14. The results are shown in Table 5. In Examples 15 to 17, AC sputtering was conducted instead of DC sputtering to form a film, and source/drain patterning was conducted by dry etching.

As for the AC sputtering, the film-forming apparatus as shown in FIG. 1 (disclosed in JP-A-2005-290550) was used.

For example, in Example 15, 6 targets 31a to 31f (each having a width of 200 mm, a length of 1700 mm and a thickness of 10 mm) fabricated in Example 1 were used. These targets 31a to 31f were arranged parallel to the direction of the width of a substrate such that they remote from each other with an interval of 2 mm. The width of the magnetic field forming means 40a to 40f was 200 mm as in the case of targets 31a to 31f.

From the gas supply system, Ar, H₂O and O₂ as the sputtering gas were respectively introduced into the system. The sputtering conditions were as follows. Sputtering pressure: 0.5 Pa, AC source power: 3 W/cm² (=10.2 kW/3400 cm²), and frequency: 10 kHz. In order to examine the film-forming speed, under the above-mentioned conditions, film formation was conducted for 10 seconds. The film thickness of the resulting thin film was measured and found to be 14 nm. The film formation speed was as high as 84 nm/min, which was suited to mass production.

The glass substrate on which a thin film had been formed was put in an electric furnace, and subjected to a heat treatment in the air at 300° C. for 60 minutes (in the air atmosphere). The thin film was cut into a size of 1 cm², and then subjected to the Hall measurement by the four point probe method. As a result, the carrier concentration was 3.20×10¹⁷ cm⁻³, indicating that the film became a sufficient semiconductor. As a result of an XRD measurement, it was confirmed that the oxide thin film was amorphous immediately after the thin film deposition, and was still amorphous after allowing it to stand in the air at 300° C. for 60 minutes. Also, by the ICP-AES analysis, it was confirmed that the atomic ratio of each element contained in the oxide thin film was the same as that of the sputtering target.

In Examples 16 and 17, the targets prepared in Examples 2 and 3 were respectively used instead of the target prepared in Example 1.

### Comparative Example 5

By using the target prepared in Comparative Example 1 instead of the targets prepared in Examples 1 to 3, in accordance with the sputtering conditions and the annealing conditions shown in Table 5, an oxide semiconductor thin film, a device for evaluating the thin film and a thin film transistor were fabricated and evaluated in the same manner as in Examples 15 to 17. In Comparative Example 5, a SiOₓ film was formed in a thickness of 100 nm by the plasma CVD method (PECVD), and on the SiOₓ film, a SiNₓ was further formed in a thickness of 150 nm, and a stacked body of the SiOₓ film and the SiNₓ film was allowed to be a protective film. The results are shown in Table 5.

As shown in Table 5, the device of Comparative Example 5 had a field effect mobility of less than 15 cm²/Vs that was significantly lower than those of the devices in Examples 15 to 17.

TABLE 5

| | | Example 15 | Example 16 | Example 17 | Com. Ex. 5 |
|---|---|---|---|---|---|
| Target composition | | In/(In + Sn + Zn + Al) = 0.25 | In/(In + Sn + | In/(In + Sn + | In/(In + Sn + |
| | | | Zn + Al) = 0.25 | Zn + Al) = 0.15 | Zn + Al) = 0.20 |
| | | Sn/(In + Sn + Zn + Al) = 0.15 | Sn/(In + Sn + | Sn/(In + Sn + | Sn/(In + Sn + |
| | | | Zn + Al) = 0.15 | Zn + Al) = 0.15 | Zn + Al) = 0.10 |
| | | Zn/(In + Sn + Zn + Al) = 0.59 | Zn/(In + Sn + | Zn/(In + Sn + | Zn/(In + Sn + |
| | | | Zn + Al) = 0.57 | Zn + Al) = 0.67 | Zn + Al) = 0.20 |
| | | Al/(In + Sn + Zn + Al) = 0.01 | Al/(In + Sn + | Al/(In + Sn + | Al/(In + Sn + |
| | | | Zn + Al) = 0.03 | Zn + Al) = 0.03 | Zn + Al) = 0.50 |
| Sputtering | Ultimate pressure (Pa) | 5.0 × 10⁻⁵ | 5.0 × 10⁻⁵ | 5.0 × 10⁻⁵ | 5.0 × 10⁻⁵ |
| conditions | Sputtering pressure (Pa) | 0.5 | 0.5 | 0.5 | 1.0 |
| | [H₂O]/([H₂O] + [Ar] + [O₂]) (%) | 0 | 1 | 1 | 0 |
| | [Ar]/([H₂O] + [Ar] + [O₂]) (%) | 90 | 99 | 94 | 50 |
| | [O₂]/([H₂O)] + [Ar] + [O₂]) (%) | 10 | 0 | 5 | 50 |
| | Water pressure (Pa) | 0 | 0.005 | 0.005 | 0 |
| | Sputtering method | AC | AC | AC | AC |
| | AC power density (W/cm²) | 3 | 5 | 5 | 5 |
| | AC frequency (Hz) | 10k | 10k | 10k | 500k |
| | Film thickness (nm) | 50 | 50 | 50 | 50 |
| | Substrate temperature (° C.) | RT | RT | 80 | RT |
| Annealing | Annealing temperature (° C.) | 300 | 300 | 300 | 300 |
| | Annealing time (min) | 60 | 60 | 60 | 60 |
| | Atmosphere | Air | Air | Air | Air |
| Half measurement | Half mobility (cm²/Vs) | 23 | 19 | 13 | 2.5 |
| | Carrier concentration (cm⁻³) | 3.20 × 10¹⁷ | 8.02 × 10¹⁶ | 5.31 × 10¹⁵ | 1.72 × 10¹⁵ |
| TFT | Channel width/Channel length (μm) | 20/5 | 20/5 | 20/5 | 20/5 |
| | Source/drain | Mo | Mo | Mo | Mo |
| | Souce/drain patterning | Dry etching | Dry etching | Dry etching | Dry etching |
| | Protective film | SiOx | SiOx | SiOx | SiOx/SiNx |
| | Mobility (cm²/Vs) | 28.1 | 23.6 | 15.3 | 3.9 |
| | Threshold voltage (V) | 1.3 | 2.5 | 2.7 | 6.0 |
| | S value (V/dec) | 0.15 | 0.12 | 0.15 | 0.58 |

### Production of Oxide Sintered Body

### Examples 18 to 22

Oxide sintered bodies of In, Sn, Zn and Al were produced in the same manner as in Examples 1 to 7, except that the atomic ratio, the temperature-elevating speed, the maximum temperature and the maximum temperature-retaining time were changed to those shown in Table 6. The results are shown in Table 6.

### [Analysis of Sintered Body]

The relative density of the sintered body obtained was measured by the Archimedean method. The sintered bodies of Examples 18 to 22 were confirmed to have a relative density of 98% or more. For the resulting sintered body, an ICP-AES analysis was conducted, and it was confirmed that the sintered body has an atomic ratio shown in Table 6.

Further, the bulk specific resistance (conductivity) of the sintered body obtained was measured by means of a resistivity meter (Loresta, manufactured by Mitsubishi Chemical Analytech Co., Ltd.) in accordance with the four point probe method (JIS R 1637). The results are shown in Table 7. As shown in Table 7, the bulk specific resistances of the sintered bodies of Examples 18 to 22 were 5 mΩcm or less.

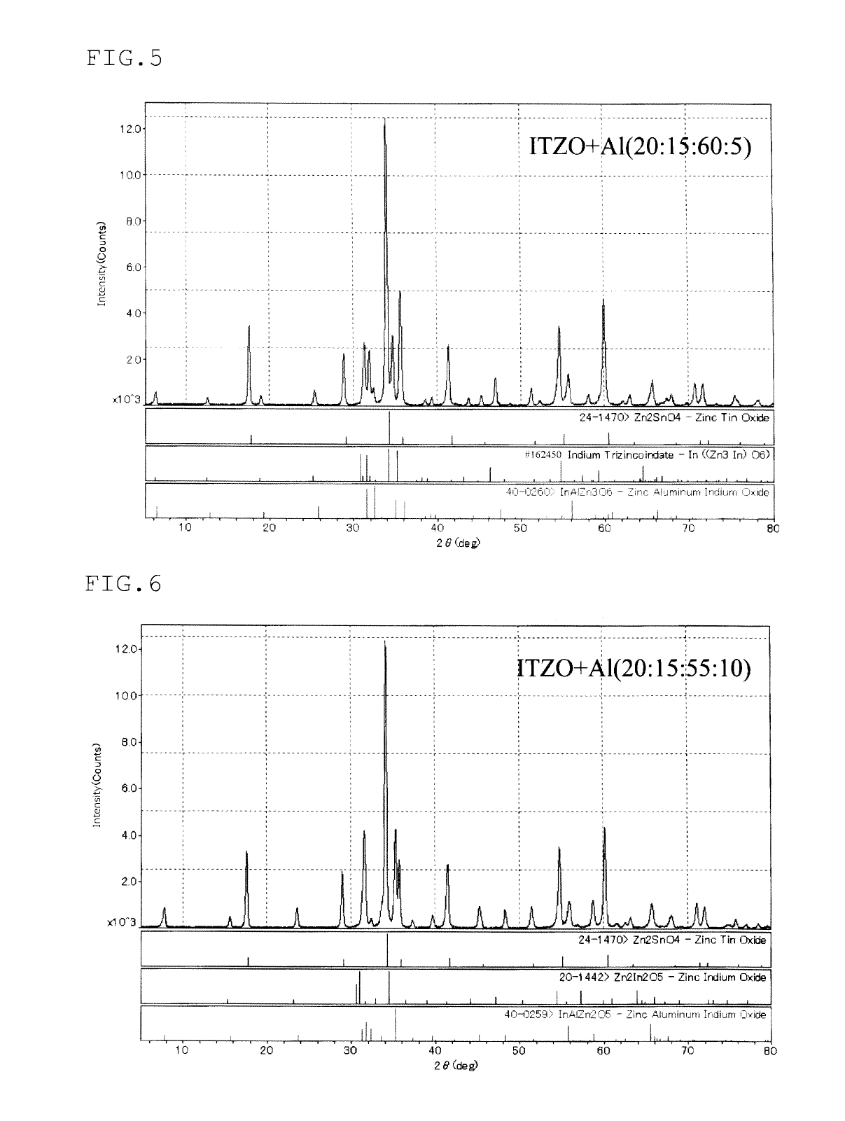

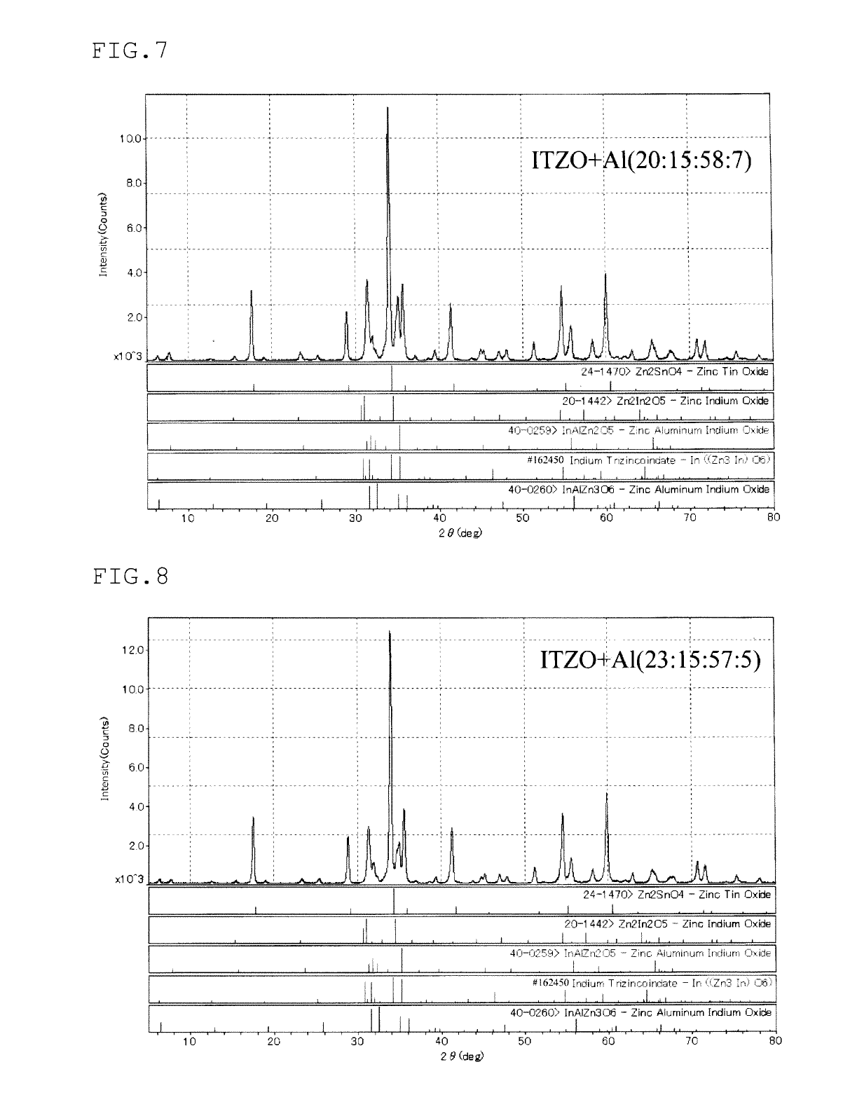

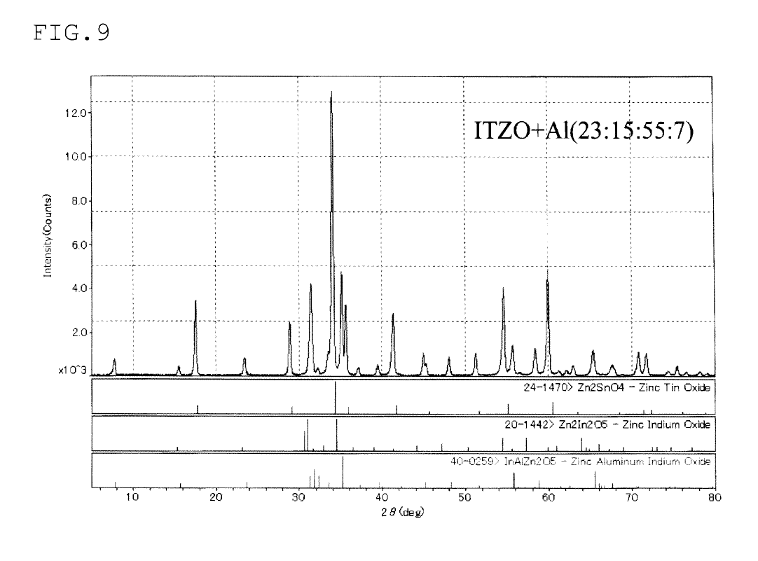

For the obtained sintered bodies, the crystal structure was examined by means of an X-ray diffraction measurement apparatus (XRD). The X-ray diffraction charts of the sintered bodies obtained in Examples 18 to 22 are respectively shown in FIGS. 5 to 9. The measurement conditions of the XRD are the same as those in Examples 1 to 7.

From the obtained X-ray diffraction chart, in the sintered body in Example 18, the homologous structure of InAlZn₃O₆, the spinel structure represented by Zn₂SnO₄ and the homologous structure represented by In₂Zn₃O₆ were observed. The crystal structure can be confirmed by the JCPDS card and/or the ICSD.

The homologous structure of InAlZn₃O₆ shows a peak pattern of No. 40-0260 of the JCPDS data base. The spinel structure of Zn₂SnO₄ shows a peak pattern of No. 24-1470 of the JCPDS database. The homologous structure of In₂Zn₃O₆ can be retrieved by X-ray diffraction from the ICSD database. It shows a peak pattern of ICSD #162450.

As a result of the calculation of the lattice constant of the homologous structure represented by In₂Zn₃O₆, it was found that a=b=3.29952 Å and c=41.91769 Å. Since the lattice constant disclosed in ICSD #162450 database is a=b=3.3520 Å and c=42.488 Å, it was confirmed that the lattice constant became small in the sintered bodies in the Examples. Since the ionic radius of Al³⁺ is smaller than the ionic radius of In³⁺, Al is in the solid solution state in the homologous structure represented by In₂Zn₃O₆, and hence the lattice constant becomes small.

In the same manner as in Example 18, an XRD measurement was conducted in the sintered bodies in Examples 19 to 22. As a result, it was found that the sintered bodies of Examples 19 to 22 contained a homologous structure compound represented by In₂O₃(ZnO)ₙ (n is 2 to 20) and a spinet structure compound represented by Zn₂SnO₄. The lattice constant of the homologous structure compound represented by In₂O₃(ZnO)ₙ (n is 2 to 20) is shown in Table 6. As shown in Table 6, also in Examples 19 to 22, it was confirmed that the lattice constant of In₂O₃(ZnO)ₙ (n is 2 to 20) was smaller than the lattice constant disclosed in the ICSD database or the JCPDS card.

For the sintered bodies of Examples 18 to 22, the dispersion of Sn and Al in the sintered body obtained by the electron probe microanalyzer (EPMA) measurement was checked. 8 μm or larger-sized aggregation of Sn or Al was not observed. As a result, the sintered bodies of Examples 18 to 22 were found to be significantly excellent in dispersivity and homogeneousness. The measurement conditions of the EPMA are the same as those in Examples 1 to 7.

### [Production of Sputtering Target]

The surface of the sintered bodies obtained in Examples 18 to 22 was ground by means of a surface grinder. The sides thereof were cut using a diamond cutter. The sintered bodies were bonded to a backing plate, thereby to obtain sputtering targets each having a diameter of 4 inches.

### [Confirmation of Presence or Absence of Abnormal Charge]

A sputtering target having a diameter of 4 inches obtained was mounted in a DC sputtering apparatus. As the atmosphere, a mixed gas obtained by adding a H₂O gas to an argon gas at a partial pressure ratio of 2% was used. A 10 kWh continuous sputtering was conducted at a DC power of 400 W with the sputtering pressure being 0.4 Pa and the substrate temperature being room temperature. Variations in voltage during the sputtering were stored in data logger to confirm the presence or absence of abnormal discharge. The results are shown in Table 7.

The above-mentioned presence or absence of abnormal discharge was determined by detecting abnormal discharge while monitoring variations in voltage. Specifically, “abnormal discharge” is defined by the case where the voltage variation generated for a measurement time of 5 minutes is 10% or more of the working voltage during sputtering operation. In particular, when the working voltage during a sputtering operation varies within a range of ±10% for 0.1 second, micro arcs, which are abnormal discharge during sputtering, may generate, thereby lowering the yield of a device. Accordingly, they may be unsuitable for mass production.

### [Confirmation of Presence or Absence of Nodule Generation]

Sputtering was conducted continuously for 40 hours by using a 4-inch-diameter sputtering target obtained with the atmosphere being a mixed gas obtained by adding a hydrogen gas to an argon gas at a partial pressure ratio of 3% to confirm the presence or absence of nodule generation. As a result, on the surface of sputtering targets of Examples 18 to 22, no nodules were observed.

The conditions at the time of the sputtering include a sputtering pressure of 0.4 Pa, a DC power of 100 W and a substrate temperature of room temperature. The hydrogen gas was added to the atmosphere gas in order to promote nodule generation.

For evaluation of nodules, the following method was employed. The change in the target surface after sputtering was observed at a magnification of 50 times by means of a stereomicroscope. The number average of nodules having a size of 20 μm or larger generated in the visual field of 3 mm² was calculated. Table 7 shows the number of nodules generated.

TABLE 6

| | | | | | First | Second | Third | | | | | |
|---|---|---|---|---|---|---|---|---|---|---|---|---|
| | In/ | Sn/ | Zn/ | Al/ | temper- | temper- | temper- | | Maximum | | | |
| | (In + | (In + | (In + | (In + | ature- | ature- | ature- | | temper- | | | |
| | Sn + | Sn + | Sn + | Sn + | elevat- | elevat- | elevat- | | ature- | | | |
| | Zn + | Zn + | Zn + | Zn + | ing | ing | ing | Maximum | retain- | | Lattice | Lattice |
| | Al) | Al) | Al) | Al) | speed | speed | speed | tempera- | ing | | constant of | constant of |
| | [Atomic | [Atomic | [Atomic | [Atomic | [° C./ | [° C./ | [° C./ | ture | time | Generated | In₂Zn₃O₆ | Zn₂In₂O₅ |
| | ratio] | ratio] | ratio] | ratio] | min] | min] | min] | [° C.] | [hr] | compounds | [Å] | [Å] |
| Exam- | 0.20 | 0.15 | 0.60 | 0.05 | 1.2 | 0.6 | 0.2 | 1450 | 25 | InAlZn₃O₆ | a = b = | |
| ple 18 | | | | | | | | | | In₂Zn₃O₆ | 3.29952 | |
| | | | | | | | | | | Zn₂SnO₄ | c = | |
| | | | | | | | | | | | 41.91769 | |
| Exam- | 0.20 | 0.15 | 0.55 | 0.10 | 1.2 | 0.6 | 0.2 | 1450 | 25 | InAlZn₂O₅ | | a = b = |
| ple 19 | | | | | | | | | | In₂Zn₂O₅ | | 3.28110 |
| | | | | | | | | | | Zn₂SnO₄ | | c = |
| | | | | | | | | | | | | 22.57396 |
| Exam- | 0.20 | 0.15 | 0.58 | 0.07 | 1.2 | 0.6 | 0.2 | 1450 | 25 | InAlZn₂O₅ | a = b = | a = b = |
| ple 20 | | | | | | | | | | InAlZn₃O₆ | 3.28901 | 3.30042 |
| | | | | | | | | | | In₂Zn₂O₅ | c = | c = |
| | | | | | | | | | | In₂Zn₃O₆ | 41.82844 | 22.65788 |
| | | | | | | | | | | Zn₂SnO₄ | | |
| Exam- | 0.23 | 0.15 | 0.57 | 0.05 | 1.2 | 0.6 | 0.2 | 1450 | 25 | InAlZn₂O₅ | a = b = | a = b = |
| ple 21 | | | | | | | | | | InAlZn₃O₆ | 3.29962 | 3.30942 |
| | | | | | | | | | | In₂Zn₂O₅ | c = | c = |
| | | | | | | | | | | In₂Zn₃O₆ | 41.99171 | 22.79170 |
| | | | | | | | | | | Zn₂SnO₄ | | |
| Exam- | 0.23 | 0.15 | 0.55 | 0.07 | 1.2 | 0.6 | 0.2 | 1450 | 25 | InAlZn₂O₅ | | a = b = |
| ple 22 | | | | | | | | | | In₂Zn₂O₅ | | 3.29855 |
| | | | | | | | | | | Zn₂SnO₄ | | c = |
| | | | | | | | | | | | | 22.69449 |

The first temperature-elevating speed means an average temperature-elevating speed at 400° C. or higher and less than 700° C.
The second temperature-elevating speed means an average temperature-elevating speed at 700° C. or higher and lower than 1100° C.
The third temperature-elevating speed means an average temperature-elevating speed at 1100° C. or higher and 1400° C. or less.

TABLE 7

| | Target relative | Bulk specific | Presence or absence of | Number of generated |
|---|---|---|---|---|
| | density | resistance | abnormal discharge | nodules |
| | [%] | [mΩcm] | during sputtering | [number/3 mm²] |
| Example 18 | 99.9 | 1.3 | None | 0 |
| Example 19 | 99.8 | 1.8 | None | 0 |
| Example 20 | 99.8 | 2.1 | None | 0 |
| Example 21 | 99.9 | 1.5 | None | 0 |
| Example 22 | 99.6 | 1.3 | None | 0 |

### Examples 23 to 30

### Production of Thin Film Transistor

As the substrate, a conductive silicon substrate with a thermally oxidized film with a thickness of 100 nm was used. The thermally oxidized film functioned as a gate insulating film, and the conductive silicon part functioned as a gate electrode. The conductive silicon substrate with a thermally oxidized film was washed with an aqueous HCN solution (washing liquid) having an extremely low concentration (1 ppm) and a pH of 10. The washing was conducted while setting the temperature to 30° C.

The 4-inch targets prepared in Examples 18 to 20 were used (Examples 23 to 25) and the 4-inch targets prepared in Examples 18 to 22 were used (Examples 26 to 30). On the gate insulating film, a 50 nm-thick amorphous thin film was formed by sputtering under the sputtering conditions and the annealing conditions shown in Tables 8 and 9. As a resist, OFPR#800 (manufactured by Tokyo Ohka Kogyo Co., Ltd.) was used. Coating, pre-baking (80° C., 5 minutes) and exposure were conducted. After development, post-baking (120° C., 5 minutes), etching with oxalic acid, and patterning into a desired shape were conducted. Thereafter, in a hot-air oven, for the devices in Examples 23 to 25, the film was subjected to a heat treatment at 450° C. for 60 minutes (annealing treatment). For the devices in Examples 26 to 30, the heating treatment (annealing treatment) was conducted at 300° C. for 60 minutes.

Thereafter, Mo (200 nm) was formed into a film by sputtering. The source/drain electrodes were patterned into a desired shape by channel etching.

After the patterning, as shown in Tables 8 and 9, as a pre-treatment for forming a protective film, a nitrous oxide plasma treatment was conducted for an oxide semiconductor film. A SiOₓ film was formed on the oxide semiconductor film in a thickness of 100 nm by the PECVD method, and further, on the SiOₓ film, a SiN_{X} film was formed in a thickness of 150 nm by the PECVD method. A stacked body of the SiOₓ film and the SiN_{X} film was allowed to be a protective film. A contact hole was formed by dry etching, whereby a back-channel etch type thin film transistor was fabricated.

For the channel layer of the thin film transistor provided with the protective film, evaluation of crystalline properties was conducted by an electron beam diffraction pattern by means of a cross-sectional TEM (Transmission Electron Microscope). As the apparatus, HF-2100 (field emission-type transmission electron microscope manufactured by Hitachi, Ltd.) was used.

A cross-sectional TEM analysis was conducted for the channel layer of the devices in Examples 23 to 25. No diffraction pattern was observed in the front channel side, showing that it was amorphous. A diffraction pattern was observed in part of the back channel side, showing that a crystallized region was present. On the other hand, as for the devices in Examples 26 to 30, no diffraction patterns were observed in both of the front channel side and the back channel side, showing that it was amorphous.

For the produced transistor, transfer characteristics were evaluated with the drain voltage (Vd) and the gate voltage (Vg) being 1V and −15 to 20V, respectively. The results are shown in Tables 8 and 9. The field effect mobility (μ) was calculated from the linear mobility, and defined as the maximum value of Vg-μ.

For the fabricated thin film transistor, a DC bias stress test was conducted. Tables 8 and 9 show a change in TFT transfer characteristics before and after application of a DC stress of Vg=15V and Vd=15V (stress temperature: 80° C. or less) for 10000 seconds.

It was revealed that the thin film transistor in Examples 23 to 30 suffered only a slight change in threshold voltage, i.e. it was hardly affected by a DC stress.

### Comparative Examples 6 and 7

By using the targets fabricated in Comparative Examples 1 and 2, back channel etch type thin film transistors were fabricated and evaluated in the same manner as in Examples 23 to 30 in accordance with the sputtering conditions and the annealing conditions shown in Table 9, except that the washing with an aqueous HCN solution (washing liquid) was not conducted and a nitrous oxide plasma treatment was not conducted for the channel. The results are shown in Table 9.

As shown in Table 9, the back channel etch type thin film transistors of Comparative Examples 6 and 7 had a field effect mobility of less than 15 cm²/Vs, that was significantly lower than those of the back channel etch type thin film transistors in Examples 22 to 30.

For the fabricated thin film transistor, a DC bias stress test was conducted. Table 9 shows a change in TFT transfer characteristics before and after application of a DC stress of Vg=15V and Vd=15V (stress temperature: 80° C. or less) for 10000 seconds.

As compared with the TFTs in Examples 23 to 30, in the thin film transistors of Comparative Examples 6 and 7, the threshold voltage was greatly shifted to the plus direction, revealing that the TFTs in these Comparative Examples had a low reliability.

A cross-sectional TEM analysis was conducted for the channel layer of the devices in Comparative Examples 6 and 7. No diffraction pattern was observed in the front channel side and the back channel side, showing that it was amorphous.

TABLE 8

| | | Example 23 | Example 24 | Example 25 | Example 26 | Example 27 |
|---|---|---|---|---|---|---|
| Target composition | | In/(In + Sn + | In/(In + Sn + | In/(In + Sn + | In/(In + Sn + | In/(In + Sn + |
| | | Zn + Al) = 0.20 | Zn + Al) = 0.20 | Zn + Al) = 0.20 | Zn + Al) = 0.20 | Zn + Al) = 0.20 |
| | | Sn/(In + Sn + | Sn/(In + Sn + | Sn/(In + Sn + | Sn/(In + Sn + | Sn/(In + Sn + |
| | | Zn + Al) = 0.15 | Zn + Al) = 0.15 | Zn + Al) = 0.15 | Zn + Al) = 0.15 | Zn + Al) = 0.15 |
| | | Zn/(In + Sn + | Zn/(In + Sn + | Zn/(In + Sn + | Zn/(In + Sn + | Zn/(In + Sn + |
| | | Zn + Al) = 0.60 | Zn + Al) = 0.55 | Zn + Al) = 0.58 | Zn + Al) = 0.60 | Zn + Al) = 0.55 |
| | | Al/(In + Sn + | Al/(In + Sn + | Al/(In + Sn + | Al/(In + Sn + | Al/(In + Sn + |
| | | Zn + Al) = 0.05 | Zn + Al) = 0.10 | Zn + Al) = 0.07 | Zn + Al) = 0.05 | Zn + Al) = 0.10 |
| Sputtering | Ultimate pressure (Pa) | 8.5 × 10⁻⁵ | 8.5 × 10⁻⁵ | 8.5 × 10⁻⁵ | 8.5 × 10⁻⁵ | 8.5 × 10⁻⁵ |
| conditions | Sputtering pressure (Pa) | 0.4 | 0.4 | 0.4 | 0.4 | 0.4 |
| | [H₂O]/([H₂O] + [Ar] + [O₂])(%) | 1 | 0 | 2 | 0 | 0 |
| | [Ar]/([H₂O] + [Ar] + [O₂))(%) | 96 | 95 | 98 | 90 | 95 |
| | [O₂]/([H₂O] + [Ar] + [O₂])(%) | 3 | 5 | 0 | 10 | 5 |
| | Water partial pressure (Pa) | 4.0 × 10⁻³ | 0 | 8.0 × 10⁻³ | 0 | 0 |
| | Sputtering method | DC | DC | DC | DC | DC |
| | T-S distance (mm) | 70 | 70 | 70 | 70 | 70 |
| | Film thickness (mm) | 50 | 50 | 50 | 50 | 50 |
| | Substrate temperature (° C.) | 25 | 25 | 25 | 25 | 25 |
| Annealing | Annealing temperature (° C.) | 450 | 450 | 450 | 300 | 300 |
| | Annealing time (min) | 60 | 60 | 60 | 60 | 60 |
| | Atmosphere | Air | Air | Air | Air | Air |
| TFT | Channel width/ | 20/10 | 20/10 | 20/10 | 20/10 | 20/10 |
| | Channel length (μm) | | | | | |
| | Source/drain | Mo | Mo | Mo | Mo | Mo |
| | Source/drain patterning | Channel etch | Channel etch | Channel etch | Channel etch | Channel etch |
| | Pre-treatment before | Nitrous oxide | Nitrous oxide | Nitrous oxide | Nitrous oxide | Nitrous oxide |
| | formation of protective film | plasma | plasma | plasma | plasma | plasma |
| | Protective film | SiOx/SiNx | SiOx/SiNx | SiOx/SiNx | SiOx/SiNx | SiOx/SiNx |
| | Mobility (cm²/Vs) | 15.2 | 15.7 | 16.3 | 17.5 | 15.1 |
| | Threshold voltage Vth(V) | 0.85 | 0.94 | 0.59 | 0.51 | 0.96 |
| | S value (V/dec) | 0.12 | 0.12 | 0.17 | 0.19 | 0.12 |
| | Threshold voltage shift [symbol] Vth(V) | 0.16 | 0.15 | 0.13 | 0.20 | 0.24 |

TABLE 9

| | | Example 28 | Example 29 | Example 30 | Comp. Ex. 6 | Comp. Ex. 7 |
|---|---|---|---|---|---|---|
| Target composition | | In/(In + Sn + | In/(In + Sn + | In/(In + Sn + | In/(In + Sn + | In/(In + Sn + |
| | | Zn + Al) = 0.20 | Zn + Al) = 0.23 | Zn + Al) = 0.23 | Zn + Al) = 0.20 | Zn + Al) = 0.15 |
| | | Sn/(In + Sn + | Sn/(In + Sn + | Sn/(In + Sn + | Sn/(In + Sn + | Sn/(In + Sn + |
| | | Zn + Al) = 0.15 | Zn + Al) = 0.15 | Zn + Al) = 0.15 | Zn + Al) = 0.10 | Zn + Al) = 0.20 |
| | | Zn/(In + Sn + | Zn/(In + Sn + | Zn/(In + Sn + | Zn/(In + Sn + | Zn/(In + Sn + |
| | | Zn + Al) = 0.58 | Zn + Al) = 0.57 | Zn + Al) = 0.55 | Zn + Al) = 0.20 | Zn + Al) = 0.15 |
| | | Al/(In + Sn + | Al/(In + Sn + | Al/(In + Sn + | Al/(In + Sn + | Al/(In + Sn + |
| | | Zn + Al) = 0.07 | Zn + Al) = 0.05 | Zn + Al) = 0.07 | Zn + Al) = 0.50 | Zn + Al) = 0.50 |
| Sputtering | Ultimate pressure (Pa) | 8.5 × 10⁻⁵ | 8.5 × 10⁻⁵ | 8.5 × 10⁻⁵ | 8.5 × 10⁻⁵ | 8.5 × 10⁻⁵ |
| conditions | Sputtering pressure (Pa) | 0.4 | 0.4 | 0.4 | 0.4 | 0.4 |
| | [H₂O]/([H₂O] + [Ar] + [O₂])(%) | 0 | 1 | 0 | 0 | 0 |
| | [Ar]/([H₂O] + [Ar] + [O₂])(%) | 90 | 96 | 90 | 50 | 60 |
| | [O₂]/([H₂O] + [Ar] + [O₂])(%) | 10 | 3 | 10 | 50 | 40 |
| | Water partial pressure (Pa) | 0 | 4.0 × 10⁻³ | 0 | 0 | 0 |
| | Sputtering method | DC | DC | DC | DC | DC |
| | T-S distance (mm) | 70 | 70 | 70 | 70 | 70 |
| | Film thickness (nm) | 50 | 50 | 50 | 50 | 50 |
| | Substrate temperature (° C.) | 25 | 25 | 25 | 25 | 25 |
| Annealing | Annealing temperature (° C.) | 300 | 300 | 300 | 300 | 300 |
| | Annealing time (min) | 60 | 60 | 60 | 60 | 60 |
| | Atmosphere | Air | Air | Air | Air | Air |
| TFT | Channel width/ | 20/10 | 20/10 | 20/10 | 20/10 | 20/10 |
| | Channel length(μm) | | | | | |
| | Source/drain | Mo | Mo | Mo | Mo | Mo |
| | Source/drain patterning | Chanel etch | Channel etch | Channel etch | Channel etch | Channel etch |
| | Pre-treatment before | Nitrous oxide | Nitrous oxide | Nitrous oxide | No treatment | No treatment |
| | formation of protective film | plasma | plasma | plasma | | |
| | Protective film | SiOx/SiNx | SiOx/SiNx | SiOx/SiNx | SiOx/SiNx | SiOx/SiNx |
| | Mobility (cm²/Vs) | 18.2 | 18.8 | 16.9 | 3.9 | 3.0 |
| | Threshold voltage Vth(V) | 1.2 | 0.97 | 1.4 | 4.3 | 3.9 |
| | S value (V/dec) | 0.19 | 0.15 | 0.12 | 0.58 | 0.65 |
| | Threshold voltage shift [symbol] Vth(V) | 0.27 | 0.23 | 0.20 | 6.2 | 5.8 |

### INDUSTRIAL APPLICABILITY

The thin film transistor obtained by using the sputtering target of the invention can be used as a display, in particular, as a large-sized display.

Although only some exemplary embodiments and/or examples of the invention have been described in detail above, those skilled in the art will readily appreciate that many modifications are possible in the exemplary embodiments and/or examples without materially departing from the novel teachings and advantages of the invention. Accordingly, all such modifications are intended to be included within the scope of the invention.

The specification of the Japanese patent application to which the present application claims priority under the Paris Convention are incorporated herein by reference in their entirety.

1. A sputtering target that comprises an oxide comprising an indium element (In), a tin element (Sn), a zinc element (Zn) and an aluminum element (Al) and comprises a homologous structure compound represented by In₂O₃(ZnO)ₙ (n is 2 to 20) and a spinel structure compound represented by Zn₂SnO₄.

2. The sputtering target according to claim 1, wherein Al is in a solid-solution state in the homologous structure compound represented by In₂O₃(ZnO)ₙ.

3. The sputtering target according to claim 1, wherein the homologous structure compound represented by In₂O₃(ZnO)ₙ is one or more selected from a homologous structure compound represented by In₂Zn₇O₁₀, a homologous structure compound represented by In₂Zn₅O₈, a homologous structure compound represented by In₂Zn₄O₇, a homologous structure compound represented by In₂Zn₃O₆ and a homologous structure compound represented by In₂Zn₂O₅.

4. The sputtering target according to claim 1 that does not comprise a bixbyite structure compound represented by In₂O₃.

5. The sputtering target according to claim 1 that satisfies the atomic ratios shown in the formulas (1) to (4):
0.08≦In/(In+Sn+Zn+Al)≦0.50 (1)
0.01≦Sn/(In+Sn+Zn+Al)≦0.30 (2)
0.30≦Zn/(In+Sn+Zn+Al)≦0.90 (3)
0.01≦Al/(In+Sn+Zn+Al)≦0.30 (4)
wherein in the formulas, In, Sn, Zn and Al are respectively an atomic ratio of the indium element, the tin element, the zinc element and the aluminum element in the sputtering target.

6. The sputtering target according to claim 1 that has a relative density of 98% or more.

7. The sputtering target according to claim 1 that has a bulk specific resistance of 5 mΩcm or less.

8. A method for producing a sputtering target, comprising:
a mixing step in which one or more compounds are mixed to prepare a mixture that at least comprises an indium element (In), a zinc element (Zn), a tin element (Sn) and an aluminum element (Al);
a forming step in which the prepared mixture is formed to obtain a formed body; and
a sintering step in which the formed body is sintered,
wherein, in the sintering step, sintering of a formed body of the oxide comprising an indium element, a zinc element, a tin element and an aluminum element is conducted by elevating the temperature of the formed body at an average temperature-elevating speed of 0.1 to 0.9° C./min from 700 to 1400° C. and by retaining the formed body at 1200 to 1650° C. for 5 to 50 hours.

9. The method for producing a sputtering target according to claim 8, wherein a first average temperature-elevating speed from 400° C. or higher and lower than 700° C. is 0.2 to 1.5° C./min, a second average temperature-elevating speed from 700° C. or higher and lower than 1100° C. is 0.15 to 0.8° C./min, and a third average temperature-elevating speed from 1100° C. or higher and 1400° C. or lower is 0.1 to 0.5° C./min, and
the relationship between the first to third average temperature-elevating speeds satisfies the relationship of:
the first average temperature-elevating speed>the second average temperature-elevating speed>the third average temperature-elevating speed.

10. An oxide semiconductor thin film obtained by a sputtering method with the use of the sputtering target according to claim 1.

11. A method for producing an oxide semiconductor thin film, wherein the film is formed by a sputtering method with the use of the sputtering target according to claim 1 in an atmosphere of a mixed gas that comprises: one or more selected from water vapor, an oxygen gas and a nitrous oxide gas; and a rare gas.

12. The method for producing an oxide semiconductor thin film according to claim 11, wherein the mixed gas is a mixed gas that at least comprises a rare gas and water vapor.

13. The method for producing an oxide semiconductor thin film according to claim 12, wherein the ratio of the water vapor contained in the mixed gas is 0.1% to 25% in terms of a partial pressure ratio.

14. The method for producing an oxide semiconductor thin film according to claim 11 comprising:
transporting substrates in sequence to positions opposing to 3 or more of the sputtering targets arranged in parallel with a prescribed interval in a vacuum chamber;
applying a negative potential and a positive potential alternately from an AC power source to each of the targets; and
causing plasma to be generated on the target by applying an output from at least one AC power source between two or more targets divergently connected to this AC power source while switching the target to which a potential is applied, thereby forming a film on a substrate surface.

15. The method for producing an oxide semiconductor thin film according to claim 14, wherein the AC power density of the AC power source is 3 W/cm² or more and 20 W/cm² or less.

16. The method for producing an oxide semiconductor thin film according to claim 14, wherein the frequency of the AC power source is 10 kHz to 1 MHz.

17. A thin film transistor comprising, as a channel layer, the oxide semiconductor thin film formed by the method for producing an oxide semiconductor thin film according to claim 11.

18. The thin film transistor according to claim 17 that has a field effect mobility of 15 cm²/Vs or more.

19. A display comprising the thin film transistor according to claim 17.
